(19) United States
(12) Patent Application Publication
(10) Pub. No.: US 2024/0006480 A1
(43) Pub. Date: Jan. 4, 2024

(54) MULTI-Vt REPLACEMENT METAL GATE BONDED STACKED FETs

(71) Applicant: INTERNATIONAL BUSINESS MACHINES CORPORATION, Armonk, NY (US)

(72) Inventors: Ruqiang Bao, Niskayuna, NY (US); Junli Wang, Slingerlands, NY (US); Dechao Guo, Niskayuna, NY (US); Heng Wu, Santa Clara, CA (US)

(21) Appl. No.: 17/852,778

(22) Filed: Jun. 29, 2022

(51) Int. Cl. H01L 29/06; H01L 29/775; H01L 29/786; H01L 27/088

(52) U.S. Cl. CPC H01L 29/0673; H01L 29/775; H01L 29/78696; H01L 27/0886

(57) ABSTRACT

A semiconductor structure is presented including a first field effect transistor (FET), the first FET including at least a first set of fins and a second set of fins, the first set of fins surrounded by a first work function metal (WFM) and the second set of fins surrounded by a second WFM and a second FET formed directly over the first FET, the second FET including at least a first nanosheet stack and a second nanosheet stack, the first nanosheet stack surrounded by a third WFM and the second nanosheet stack surrounded by a third WFM with dipoles. The semiconductor structure further includes first contacts disposed from the first and second WFMs of the first FET to back-end-of-line (BEOL) components and second contacts disposed from a backside power delivery network (BSPDN) through the third WFM of the second FET to a top surface of the first and second WFMs of the first FET.

### BACKGROUND

The present invention relates generally to semiconductor devices, and more specifically, to multi-threshold voltage (Vt) replacement metal gate bonded stacked field effect transistors (FETs).

Multi-Vt devices (e.g., devices including a plurality of transistors having a range of different threshold voltages (Vt)) are used to optimize power consumption and/or minimize computing delays in circuit applications. Field effect transistors (FETs) having lower Vts are able to switch relatively quickly, but are prone to higher power leakage. In contrast, FETs having higher Vts conserve power by reducing static power leakage, but exhibit higher switching delays. As such, multi-Vt devices using FETs with lower Vts on time-critical paths and FETs with higher Vts on non-time-critical paths may provide improved performance in terms of computing speed and power consumption. Advances in semiconductor engineering have enabled a dramatic scaling (scale down) in device size. Architectures such as fin field effect transistors (finFETs), gate all around FETs (GAA-FETs) and replacement metal gate FETs (RMG-FETs) exist to address certain issues at scaled nodes. However, such architectures do not specifically address issues in multi-Vt devices. Accordingly, new methods of producing FETs with modulated Vts that are compatible with developing nodes are desired.

### SUMMARY

In accordance with an embodiment, a semiconductor structure is provided. The semiconductor structure includes a first field effect transistor (FET), the first FET including at least a first set of fins and a second set of fins, the first set of fins surrounded by a first work function metal (WFM) and the second set of fins surrounded by a second WFM, a second FET disposed directly over the first FET, the second FET including at least a first nanosheet stack and a second nanosheet stack, the first nanosheet stack surrounded by a third WFM and the second nanosheet stack surrounded by a third WFM with dipoles, first contacts disposed from the first and second WFMs of the first FET to back-end-of-line (BEOL) components, and second contacts disposed from a backside power delivery network (BSPDN) through the third WFM of the second FET to a top surface of the first and second WFMs of the first FET.

In accordance with another embodiment, a semiconductor structure is provided. The semiconductor structure includes a first field effect transistor (FET), the first FET including at least a first set of fins and a second set of fins, the first set of fins surrounded by a first work function metal (WFM) and the second set of fins surrounded by a second WFM, a second FET disposed directly over the first FET, the second FET including at least a first nanosheet stack and a second nanosheet stack, the first nanosheet stack surrounded by a third WFM and the second nanosheet stack surrounded by a fourth WFM, first contacts disposed from the first and second WFMs of the first FET to back-end-of-line (BEOL) components, and second contacts disposed from a backside power delivery network (BSPDN), one second contact extending through the fourth WFM of the second FET to a top surface of the second WFM of the first FET.

In accordance with yet another embodiment, a semiconductor structure is provided. The semiconductor structure includes a first field effect transistor (FET), the first FET including at least a first nanosheet stack and a second nanosheet stack, the first nanosheet stack surrounded by a first work function metal (WFM) and the second nanosheet stack surrounded by a second WFM, a second FET disposed directly over the first FET, the second FET including a third nanosheet stack and a fourth nanosheet stack, the third nanosheet stacks surrounded by a third WFM and the fourth nanosheet stacks surrounded by a fourth WFM, first contacts disposed from the first and second WFMs of the first FET to back-end-of-line (BEOL) components, and second contacts disposed from a backside power delivery network (BSPDN) to the third WFM of the second FET.

It should be noted that the exemplary embodiments are described with reference to different subject-matters. In particular, some embodiments are described with reference to method type claims whereas other embodiments have been described with reference to apparatus type claims. However, a person skilled in the art will gather from the above and the following description that, unless otherwise notified, in addition to any combination of features belonging to one type of subject-matter, also any combination between features relating to different subject-matters, in particular, between features of the method type claims, and features of the apparatus type claims, is considered as to be described within this document.

These and other features and advantages will become apparent from the following detailed description of illustrative embodiments thereof, which is to be read in connection with the accompanying drawings.

### BRIEF DESCRIPTION OF THE DRAWINGS

The invention will provide details in the following description of preferred embodiments with reference to the following figures wherein:

FIG. 1 is a cross-sectional view of a semiconductor structure including a nanosheet stack formed over a substrate, in accordance with an embodiment of the present invention;

FIG. 2 is a cross-sectional view of the semiconductor structure of FIG. 1 where source/drain epi regions, an interlayer dielectric (ILD), spacers, and inner spacers are formed/deposited, and where the sacrificial layers of the nanosheet stack are removed, in accordance with an embodiment of the present invention;

FIG. 3 is a cross-sectional view of the semiconductor structure of FIG. 2 where a dummy gate, interfacial layers (IL), and high-k (HK) dielectric layers are deposited to form a bottom field effect transistor (FET) including nanosheet stacks, in accordance with an embodiment of the present invention;

FIG. 4 is a cross-sectional view of the semiconductor structure of FIG. 3 where a top FET is formed including vertical fins, the top FET formed over the bottom FET, in accordance with an embodiment of the present invention;

FIG. 5 is a cross-sectional view of the semiconductor structure of FIG. 4 where the dummy gates of the top FET are replaced with different replacement metal gates and isolation walls are formed, in accordance with an embodiment of the present invention;

FIG. 6 is a cross-sectional view of the semiconductor structure of FIG. 5 where contacts are formed to the replacement metal gates of the top FET, back-end-of-line (BEOL) processing takes place, and a carrier wafer is bonded to the BEOL, in accordance with an embodiment of the present invention;

FIG. 7 is a cross-sectional view of the semiconductor structure of FIG. 6 where the structure is flipped and openings are made to the dummy gate of the bottom FET, in accordance with an embodiment of the present invention;

FIG. 8 is a cross-sectional view of the semiconductor structure of FIG. 7 where the dummy gate is selectively removed and a replacement metal gate is deposited in the bottom FET, in accordance with an embodiment of the present invention;

FIG. 9 is a cross-sectional view of the semiconductor structure of FIG. 8 where isolation walls are formed between the nanosheet stacks, contacts are formed to the replacement metal gates of the top FET and a backside power delivery network (BSPDN) is connected, in accordance with an embodiment of the present invention;

FIG. 10 is a cross-sectional view of a semiconductor structure where thick isolation walls are formed to separate fins of the top FET and the dummy gates of the top FET are replaced with different replacement metal gates, in accordance with another embodiment of the present invention;

FIG. 11 is a cross-sectional view of the semiconductor structure of FIG. 10 where contacts are formed to the replacement metal gates of the top FET, BEOL processing takes place, and a carrier wafer is bonded to the BEOL, in accordance with an embodiment of the present invention;

FIG. 12 is a cross-sectional view of the semiconductor structure of FIG. 11 where the structure is flipped and openings are made to the dummy gate of the bottom FET, in accordance with an embodiment of the present invention;

FIG. 13 is a cross-sectional view of the semiconductor structure of FIG. 12 where the dummy gate is selectively removed, a replacement metal gate is deposited in the bottom FET, and thick isolation walls are formed in the bottom FET to separate the nanosheet stacks, in accordance with an embodiment of the present invention;

FIG. 14 is a cross-sectional view of the semiconductor structure of FIG. 13 where contacts are formed to the replacement metal gates of the top FET and a backside power delivery network (BSPDN) is connected, in accordance with another embodiment of the present invention;

FIG. 15 is a cross-sectional view of a semiconductor structure similar to FIGS. 10 and 11, where the structure is flipped, a single thick isolation wall is formed through the dummy gate of the bottom FET, and a single opening is made to the dummy gate of the bottom FET, in accordance with another embodiment of the present invention;

FIG. 16 is a cross-sectional view of the semiconductor structure of FIG. 15 where the dummy gate is selectively removed, and different replacement metal gate are formed on opposed ends of the single thick isolation wall, in accordance with an embodiment of the present invention;

FIG. 17 is a cross-sectional view of the semiconductor structure of FIG. 16 where two more isolation walls are formed on opposed ends of the first isolation wall, contacts are formed to the replacement metal gates of the top FET and a backside power delivery network (BSPDN) is connected, in accordance with an embodiment of the present invention;

FIG. 18 is a cross-sectional view of a semiconductor structure including a nanosheet stack formed over a substrate, where an etch stop layer and an isolation layer including silicon germanium (SiGe) with a high concentration of germanium (Ge) are formed between the substrate and the nanosheet stack, in accordance with another embodiment of the present invention;

FIG. 19 is a cross-sectional view of the semiconductor structure of FIG. 18 where source/drain epi regions, an interlayer dielectric (ILD), spacers, inner spacers, and a dummy gate are formed/deposited, and where the sacrificial layers of the nanosheet stack are removed to complete the bottom FET having nanosheet stacks, in accordance with an embodiment of the present invention;

FIG. 20 is a cross-sectional view of the semiconductor structure of FIG. 19 where a top FET is formed including nanosheet stacks, the top FET formed over the bottom FET, in accordance with an embodiment of the present invention;

FIG. 21 is a cross-sectional view of the semiconductor structure of FIG. 20 where the dummy gates of the top FET are replaced with replacement metal gates and where contacts are formed to the replacement metal gates, back-end-of-line (BEOL) processing takes place, and a carrier wafer is bonded to the BEOL, in accordance with an embodiment of the present invention;

FIG. 22 is a cross-sectional view of the semiconductor structure of FIG. 21 where the structure is flipped, the substrate and etch stop layer are removed, the dummy gate is removed, and a replacement metal gate is deposited around the bottom nanosheet stacks, in accordance with an embodiment of the present invention;

FIG. 23 is a cross-sectional view of the semiconductor structure of FIG. 22 where isolation walls are formed to isolate the bottom nanosheet stacks, contacts are formed to the replacement metal gate of the bottom FET, and a backside power delivery network (BSPDN) is connected, in accordance with an embodiment of the present invention;

FIG. 24 is a cross-sectional view of a semiconductor structure including a nanosheet stack formed over a substrate, where an etch stop layer and a SiGe layer with a low concentration of Ge are formed between the substrate and the nanosheet stack, in accordance with another embodiment of the present invention;

FIG. 25 is a cross-sectional view of the semiconductor structure of FIG. 24 where a dummy gate is deposited and the nanosheet stack is recessed to form fins, in accordance with an embodiment of the present invention;

FIG. 26 is a cross-sectional view of the semiconductor structure of FIG. 25 where an oxide layer and a nitride layer are deposited, and a silicon germanium (SiGe) layer with a low concentration of germanium (Ge) is selectively removed, in accordance with an embodiment of the present invention;

FIG. 27 is a cross-sectional view of the semiconductor structure of FIG. 26 where an etch stop layer is deposited, in accordance with an embodiment of the present invention;

FIG. 28 is a cross-sectional view of the semiconductor structure of FIG. 27 where the etch stop layer is etched back such that etch stop layer portions remain directly under the nanosheets stacks of the bottom FET, in accordance with an embodiment of the present invention;

FIG. 29 is a cross-sectional view of the semiconductor structure of FIG. 28 where an oxide layer is deposited to complete the bottom FET, in accordance with an embodiment of the present invention;

FIG. 30 is a cross-sectional view of the semiconductor structure of FIG. 29 where the top FET is formed over the bottom FET, in accordance with an embodiment of the present invention;

FIG. 31 is a cross-sectional view of the semiconductor structure of FIG. 30 where the dummy gates of the top FET are replaced with different replacement metal gates, contacts are formed to the replacement metal gates, BEOL processing is performed, and wafer boding takes place, in accordance with an embodiment of the present invention;

FIG. 32 is a cross-sectional view of the semiconductor structure of FIG. 31 where the structure is flipped, the substrate and etch stop layer are removed to expose the etch stop layer portions directly underneath the nanosheet stacks, the dummy gate is selectively removed, and a replacement metal gate is deposited around the bottom nanosheet stacks, in accordance with an embodiment of the present invention; and

FIG. 33 is a cross-sectional view of the semiconductor structure of FIG. 32 where isolation walls are formed within the bottom FET, self-aligned contacts (SACs) are formed and a backside power delivery network (BSPDN) is connected, in accordance with an embodiment of the present invention.

Throughout the drawings, same or similar reference numerals represent the same or similar elements.

### DETAILED DESCRIPTION

Embodiments in accordance with the present invention provide methods and devices for constructing stacked field effect transistors (FETs) having multi-Vt replacement metal gates. Some concerns for existing stacked FET structures are that the thermal budget of the top FET does not degrade the gate stack, being able to provide a multi-Vt solution, that is, metal gate patterning and dipole patterning, and being able to have both shared gates and independent gates. The exemplary embodiments of the present invention address such issues by providing novel structures for improved in-gate stack thermal budgets.

Examples of semiconductor materials that can be used in forming such nanosheet structures include silicon (Si), germanium (Ge), silicon germanium alloys (SiGe), silicon carbide (SiC), silicon germanium carbide (SiGeC), III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements.

It is to be understood that the present invention will be described in terms of a given illustrative architecture; however, other architectures, structures, substrate materials and process features and steps/blocks can be varied within the scope of the present invention. It should be noted that certain features cannot be shown in all figures for the sake of clarity. This is not intended to be interpreted as a limitation of any particular embodiment, or illustration, or scope of the claims.

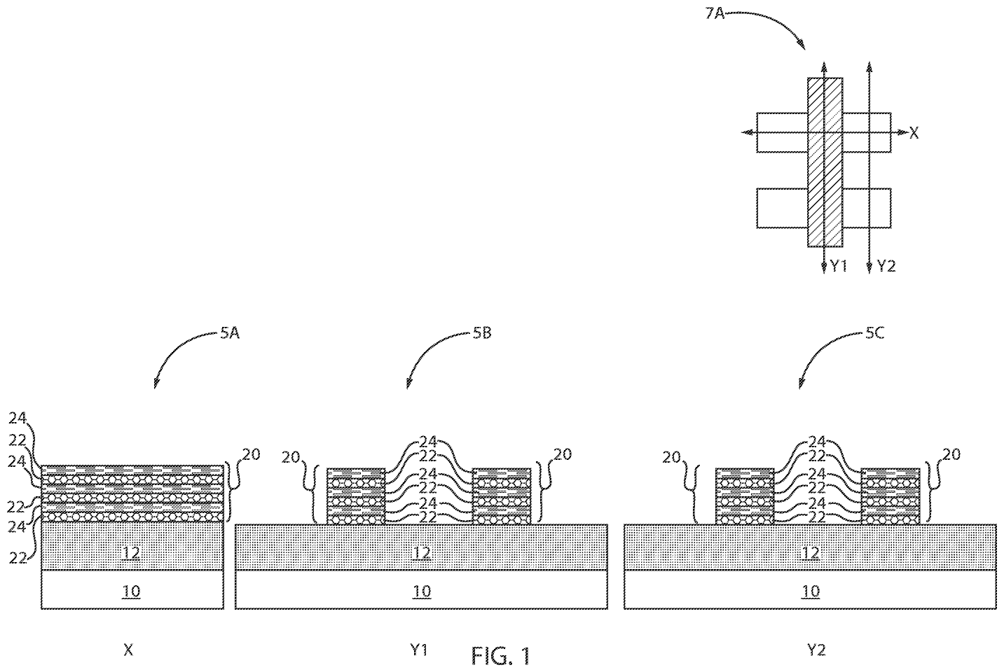

FIG. 1 is a cross-sectional view of a semiconductor structure including a nanosheet stack formed over a substrate, in accordance with an embodiment of the present invention.

In various example embodiments, a nanosheet stack 20 is formed over a substrate 10. A buried oxide (BOX) layer 12 can be formed between the substrate 10 and the nanosheet stack 20. The nanosheet stack 20 includes alternating layers of a first semiconductor material (or layer) 22 and a second semiconductor material (or layer) 24. The first semiconductor material 22 can be, e.g., silicon germanium (SiGe) and the second semiconductor material 24 can be, e.g., silicon (Si).

Structure 5A is a cross-section along axis X as shown in the top view 7A.

Structure 5B is a cross-section along axis Y1 as shown in the top view 7A.

Structure 5C is a cross-section along axis Y2 as shown in the top view 7A.

In one or more embodiments, the substrate 10 can be a semiconductor or an insulator with an active surface semiconductor layer. The substrate 10 can be crystalline, semi-crystalline, microcrystalline, or amorphous. The substrate 10 can be essentially (e.g., except for contaminants) a single element (e.g., silicon), primarily (e.g., with doping) of a single element, for example, silicon (Si) or germanium (Ge), or the substrate 10 can include a compound, for example, Al₂O₃, SiO₂, GaAs, SiC, or SiGe. The substrate 10 can also have multiple material layers, for example, a semiconductor-on-insulator substrate (SeOI), a silicon-on-insulator substrate (SOI), germanium-on-insulator substrate (GeOI), or silicon-germanium-on-insulator substrate (SGOI). The substrate 10 can also have other layers forming the substrate 10, including high-k oxides and/or nitrides. In one or more embodiments, the substrate 10 can be a silicon wafer. In an embodiment, the substrate 10 is a single crystal silicon wafer.

Referring to, e.g., the nanosheet stack 20, the first semiconductor material 22 can be the first layer in a stack of sheets of alternating materials. The nanosheet stack 20 thus includes first semiconductor materials (or layers) 22 and second semiconductor materials (or layers) 24. Although it is specifically contemplated that the first semiconductor materials 22 can be formed from silicon germanium and that the second semiconductor materials 24 can be formed from silicon, it should be understood that any appropriate materials can be used instead, as long as the two semiconductor materials have etch selectivity with respect to one another. As used herein, the term “selective” in reference to a material removal process denotes that the rate of material removal for a first material is greater than the rate of removal for at least another material of the structure to which the material removal process is being applied. The alternating semiconductor materials 22/24 can be deposited by any appropriate mechanism. It is specifically contemplated that the first and second semiconductor materials 22/24 can be epitaxially grown from one another, but alternate deposition processes, such as chemical vapor deposition (CVD), physical vapor deposition (PVD), atomic layer deposition (ALD), or gas cluster ion beam (GCIB) deposition, are also contemplated.

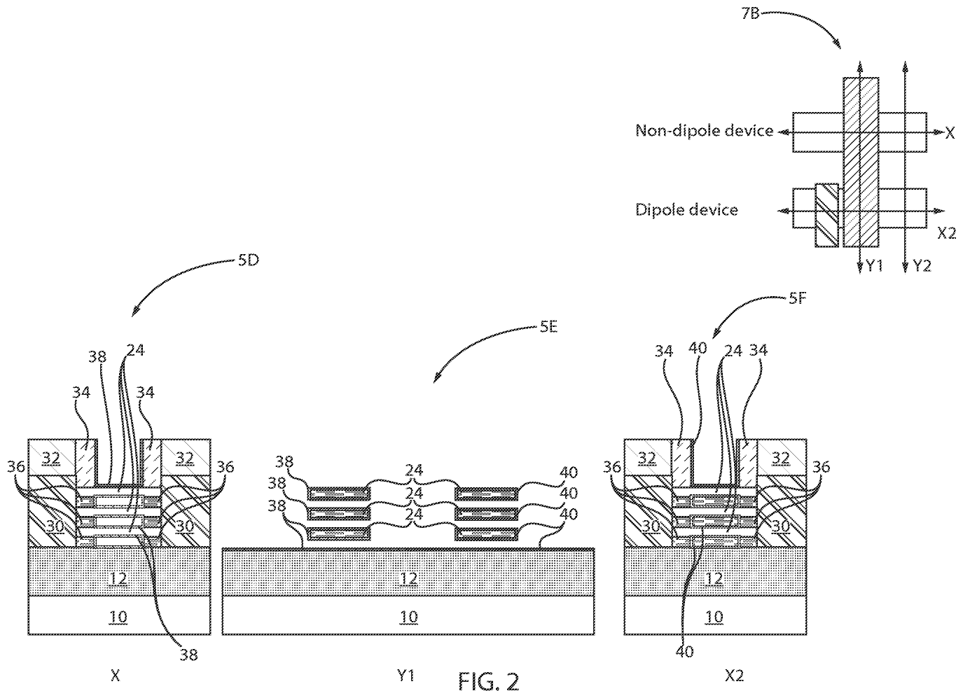

FIG. 2 is a cross-sectional view of the semiconductor structure of FIG. 1 where source/drain epi regions, an interlayer dielectric (ILD), spacers, and inner spacers are formed/deposited, and where the sacrificial layers of the nanosheet stack are removed, in accordance with an embodiment of the present invention.

In various example embodiments, bottom source/drain (S/D) epi regions 30 are formed. An ILD 32 is formed over the bottom S/D epi regions 30. Spacers 34 are formed adjacent the ILD 32. The sacrificial layers (e.g., SiGe layers) of the nanosheet stacks 20 are selectively removed and inner spacers 36 are formed. A first interfacial layer (IL) 38 surrounds the remaining Si layers 24 of one nanosheet stack 20. A second interfacial layer (IL) 40 surrounds the remaining Si layers 24 of another nanosheet stack 20.

Structure 5D is a cross-section along axis X as shown in the top view 7B. In structure the first IL 38 directly contacts the remaining Si layers 24 of one nanosheet stack 20.

Structure 5E is a cross-section along axis Y1 as shown in the top view 7B. In structure both the first and second ILs 38, 40 are visible.

Structure 5F is a cross-section along axis X2 as shown in the top view 7B. In structure the second IL 40 directly contacts the remaining Si layers 24 of another nanosheet stack 20.

The terms “epitaxial growth” and “epitaxial deposition” refer to the growth of a semiconductor material on a deposition surface of a semiconductor material, in which the semiconductor material being grown has substantially the same crystalline characteristics as the semiconductor material of the deposition surface. The term “epitaxial material” denotes a material that is formed using epitaxial growth. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

The ILD 32 can be any suitable material, such as, for example, porous silicates, carbon doped oxides, silicon dioxides, silicon nitrides, silicon oxynitrides, or other dielectric materials. Any known manner of forming the ILD 32 can be utilized. The ILD 32 can be formed using, for example, CVD, PECVD, ALD, flowable CVD, spin-on dielectrics, or PVD.

The spacers 34 and the inner spacers 36 can include any of one or more of SiN, SiBN, SiCN and/or SiBCN films.

The ILs 38, 40 can be deposited by any appropriate method, such as ALD, CVD, and ozone oxidation. The ILs 38, 40 can include, e.g., oxide, HfSiO and oxynitride.

The etching can include a dry etching process such as, for example, reactive ion etching, plasma etching, ion etching or laser ablation. The etching can further include a wet chemical etching process in which one or more chemical etchants are used to remove portions of the blanket layers that are not protected by the patterned photoresist.

In some examples, the selective wet etch or the selective dry etch can selectively remove the portions of first semiconductor material 22 (e.g., the SiGe layer) and leave the entirety or portions of the second semiconductor material 24. The removal creates gaps or openings or indentations between the second semiconductor materials 24.

The dry and wet etching processes can have etching parameters that can be tuned, such as etchants used, etching temperature, etching solution concentration, etching pressure, source power, RF bias voltage, RF bias power, etchant flow rate, and other suitable parameters. Dry etching processes can include a biased plasma etching process that uses a chlorine-based chemistry. Other dry etchant gasses can include Tetrafluoromethane (CF₄), nitrogen trifluoride (NF₃), sulfur hexafluoride (SF₆), and helium (He), and Chlorine trifluoride (ClF₃). Dry etching can also be performed anisotropically using such mechanisms as DRIE (deep reactive-ion etching). Chemical vapor etching can be used as a selective etching method, and the etching gas can include hydrogen chloride (HCl), Tetrafluoromethane (CF₄), and gas mixture with hydrogen (H₂). Chemical vapor etching can be performed by CVD with suitable pressure and temperature.

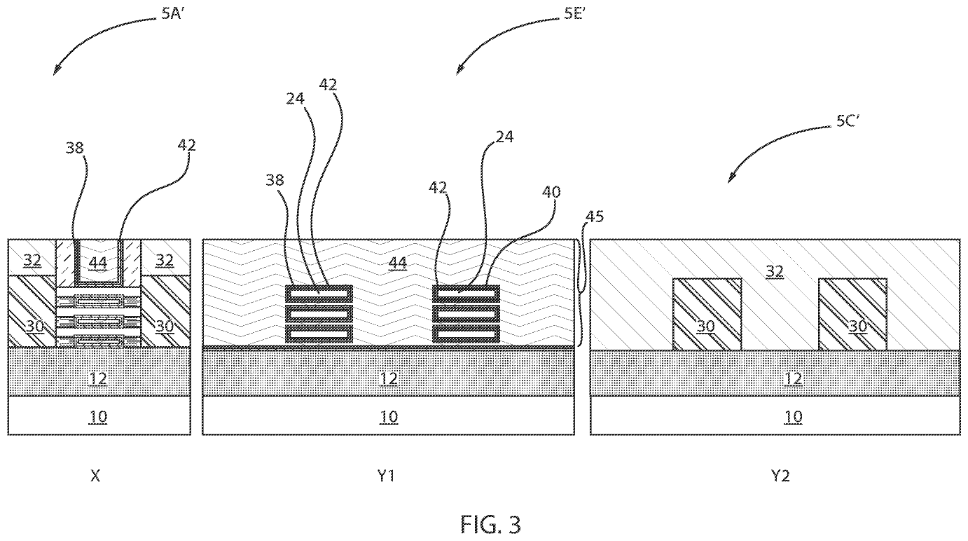

FIG. 3 is a cross-sectional view of the semiconductor structure of FIG. 2 where a dummy gate, interfacial layers (IL), and high-k (HK) dielectric layers are deposited to form a bottom field effect transistor (FET) including nanosheet stacks, in accordance with an embodiment of the present invention.

In various example embodiments, a HK dielectric layer 42 surrounds the ILs 38, 40. A dummy gate 44 is then deposited to surround the nanosheet stacks 20. The bottom FET 45 is complete.

The structure 5A′ depicts the dummy gate in the X direction.

The structure 5E′ depicts the dummy gate surrounding both nanosheet stacks 20 in the Y1 direction.

The structure 5C′ depicts the bottom S/D epi regions 30 and the ILD 32 in the Y2 direction.

The HK dielectric layer 42 can be deposited over and wrapped around the ILs 38, 40 by any suitable techniques, such as ALD, CVD, metal-organic CVD (MOCVD), physical vapor deposition (PVD), thermal oxidation, combinations thereof, or other suitable techniques. The HK dielectric layer 42 can include, e.g., LaO, AlO, ZrO, TiO, Ta₂O₅, Y₂O₃, SrTiO₃(STO), BaTiO₃(BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), or other suitable materials. HK dielectric layer 42 can include a single layer or multiple layers, such as metal layer, liner layer, wetting layer, and adhesion layer. In other embodiments, the HK dielectric layer 42 can include, e.g., Ti, Ag, Al, TiAlN, TaC, TaCN, TaSiN, Mn, Zr, TiN, TaN, Ru, Mo, Al, WN, Cu, W, or any suitable materials.

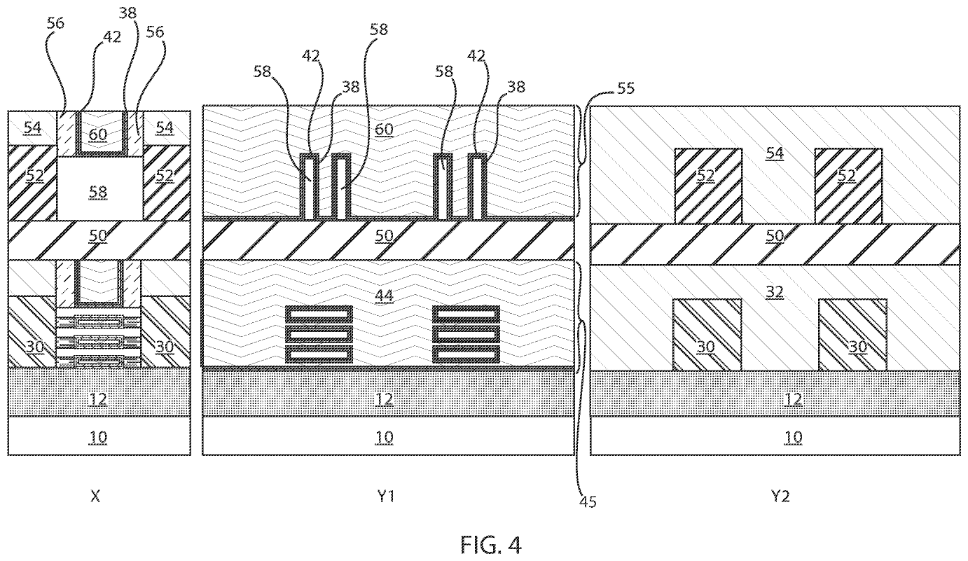

FIG. 4 is a cross-sectional view of the semiconductor structure of FIG. 3 where a top FET is formed including vertical fins, the top FET formed over the bottom FET, in accordance with an embodiment of the present invention.

In various example embodiments, a top FET 55 is formed. A bonding oxide 50 is deposited over the bottom FET 45. The top FET 55 is formed over the bonding oxide 50. The top FET 55 includes top S/D epi regions 52. An ILD 54 is formed over the top S/D epi regions 52. Spacers 56 are formed adjacent the ILD 54. Fins 58 are formed between the top S/D epi regions 52. A first interfacial layer (IL) 38 surrounds the fins 58. A high-k (HK) dielectric layer 42 surrounds the IL 38. A dummy gate 60 is then deposited.

Therefore, the bottom FET 45 includes nanosheet stacks 20, whereas the top FET 55 includes the fins 58. The bonding oxide 50 separates the bottom FET 45 from the top FET 55. Stated differently, the bonding oxide 50 bonds the bottom FET 45 to the top FET 55.

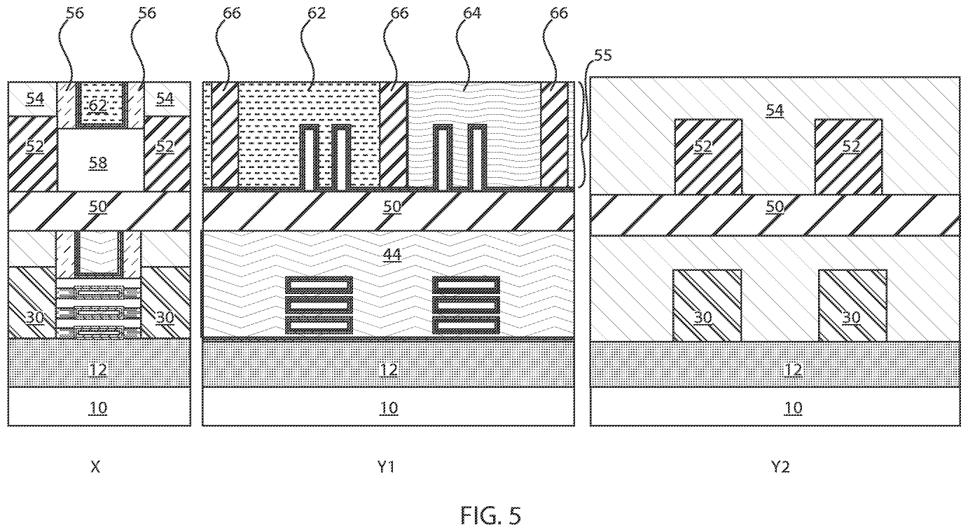

FIG. 5 is a cross-sectional view of the semiconductor structure of FIG. 4 where the dummy gates of the top FET are replaced with different replacement metal gates and isolation walls are formed, in accordance with an embodiment of the present invention.

In various example embodiments, the dummy gate 60 is replaced with a first work function metal (WFM) 62 and a second WFM 64. The first WFM 62 encompasses a first set of fins and the second WFM 64 encompasses a second set of fins. Isolation walls 66 are also formed. In the instant case, three isolation walls 66 are formed. The isolation walls 66 separate the first WFM 62 from the second WFM 64. The isolation walls 66 extend to the top surface of the bonding oxide 50. All the isolation walls 66 can have an equal width.

The first and second WFMs 62, 64 can be metals, such as, e.g., copper (Cu), cobalt (Co), aluminum (Al), platinum (Pt), gold (Au), tungsten (W), titanium (Ti), nitride (N) or any combination thereof. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. In various exemplary embodiments, the height of the WFMs 62, 64 can be reduced by chemical-mechanical polishing (CMP) and/or etching. Therefore, the planarization process can be provided by CMP. Other planarization process can include grinding and polishing.

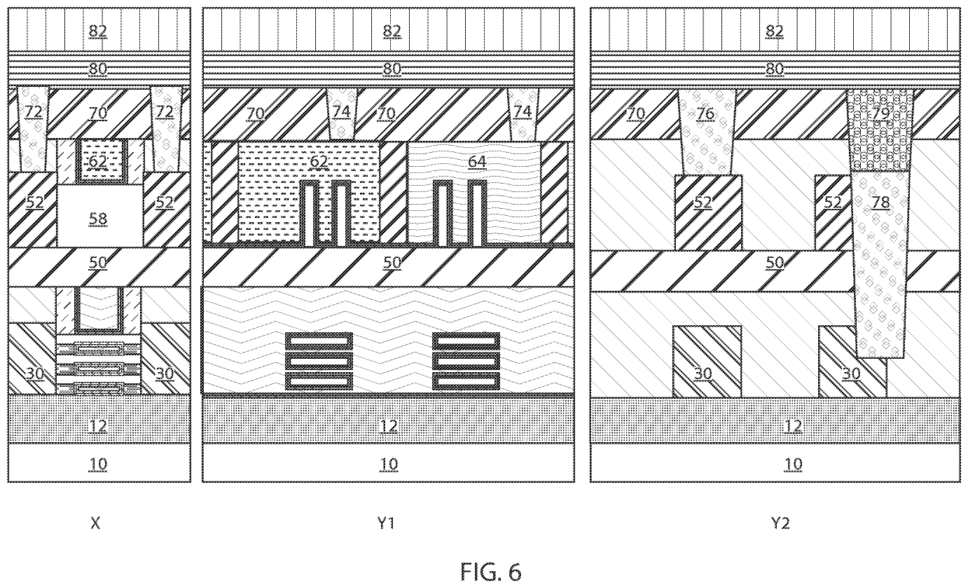

FIG. 6 is a cross-sectional view of the semiconductor structure of FIG. 5 where contacts are formed to the replacement metal gates of the top FET, back-end-of-line (BEOL) processing takes place, and a carrier wafer is bonded to the BEOL, in accordance with an embodiment of the present invention.

In various example embodiments, an ILD 70 is deposited over the first and second WFMs 62, 64 in the Y1 direction. The ILD 70 is also present over the top S/D epi regions 52 in the X direction and over the bottom S/D epi regions 30 in the Y2 direction.

Contacts 74 are formed to the top surface of the first WFM 62 and the second WFM 64. The contacts 74 are referred to as CB contacts. CB contacts are gate contacts. Contacts 72 are formed to the top surface of the top S/D epi regions 52 in the X direction. The contacts 72 are referred to as CA contacts. CA contacts are S/D contacts. Contact 76 is formed to the top surface of the top S/D epi region 52 in the Y2 direction. The contact 76 is also a CA contact or S/D contact. Additionally, contact 78 is formed through the bonding oxide 50 to the bottom S/D epi region 30. A dielectric cap 79 is formed over the contact 78. The BEOL 80 directly contacts the top surfaces of the CA contacts 72, 76 and the CB contacts 74. A carrier wafer 82 is then bonded to the BEOL 80. The BEOL 80 can include various components.

Non-limiting examples of suitable conductive materials for the CA contacts 72, 76 and the CB contacts 74 include doped polycrystalline or amorphous silicon, germanium, silicon germanium, a metal (e.g., tungsten, titanium, tantalum, ruthenium, zirconium, cobalt, copper, aluminum, lead, platinum, tin, silver, gold), a conducting metallic compound material (e.g., tantalum nitride, titanium nitride, tantalum carbide, titanium carbide, titanium aluminum carbide, tungsten silicide, tungsten nitride, ruthenium oxide, cobalt silicide, nickel silicide), carbon nanotube, conductive carbon, graphene, or any suitable combination of these materials. The conductive material can further include dopants that are incorporated during or after deposition. The conductive metal can be deposited by a suitable deposition process, for example, CVD, PECVD, PVD, plating, thermal or e-beam evaporation, and sputtering.

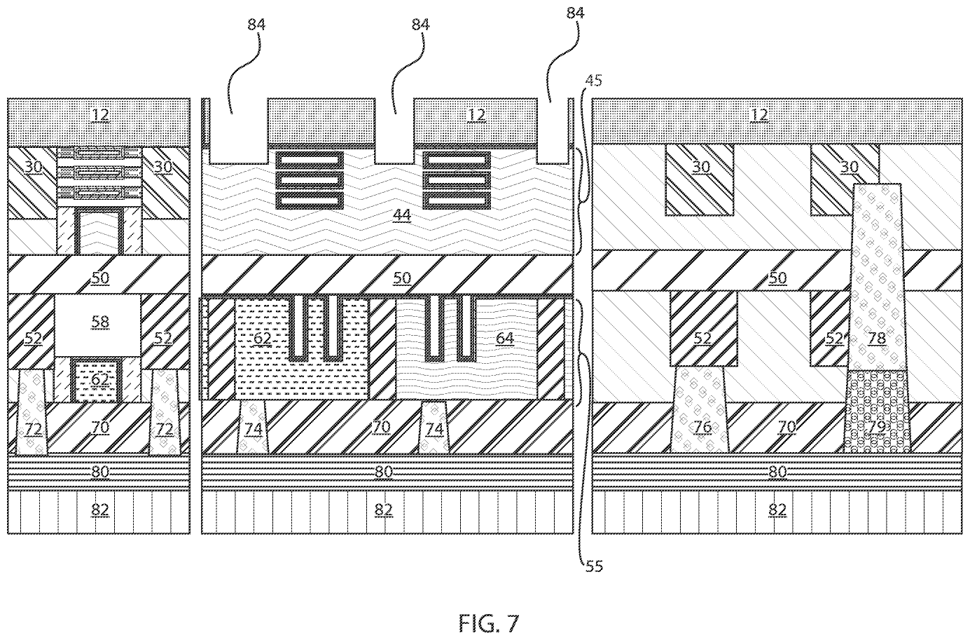

FIG. 7 is a cross-sectional view of the semiconductor structure of FIG. 6 where the structure is flipped and openings are made to the dummy gate of the bottom FET, in accordance with an embodiment of the present invention.

In various example embodiments, the structure is flipped and openings 84 are made through the BOX layer 12 to the dummy gate 44 of the bottom FET 45. The substrate 10 has been selectively removed.

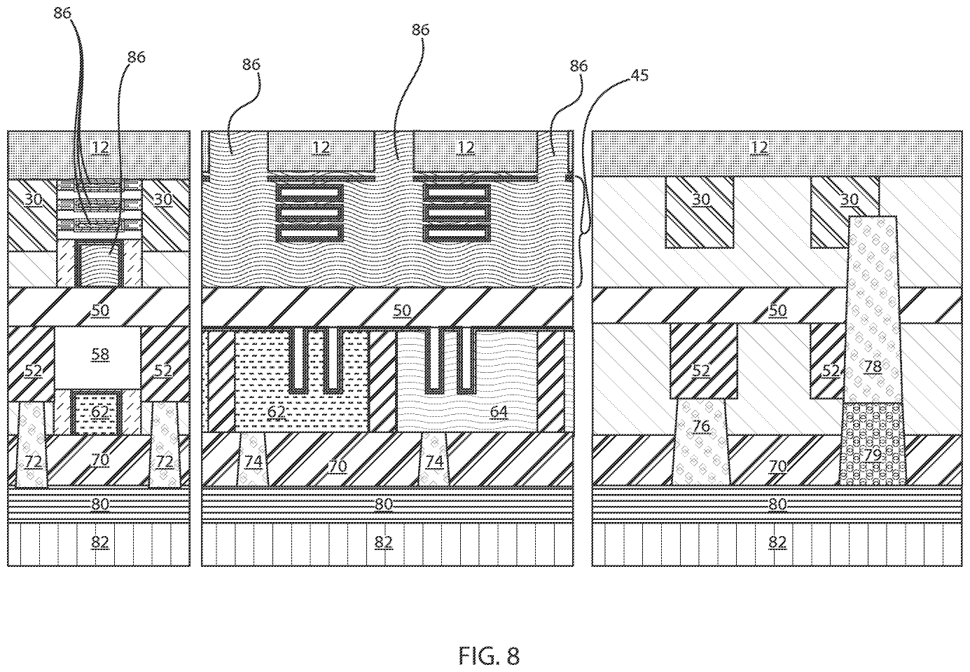

FIG. 8 is a cross-sectional view of the semiconductor structure of FIG. 7 where the dummy gate is selectively removed and a replacement metal gate is deposited in the bottom FET, in accordance with an embodiment of the present invention.

In various example embodiments, the dummy gate 44 is selectively removed and a replacement metal gate or WFM 86 is deposited in the bottom FET 45. The WFM 86 can be referred to as a third WFM. The WFM 86 surrounds the nanosheets stacks. This results in 3 different WFMs being present in the structure, where each of the WFMs can be composed of a different material.

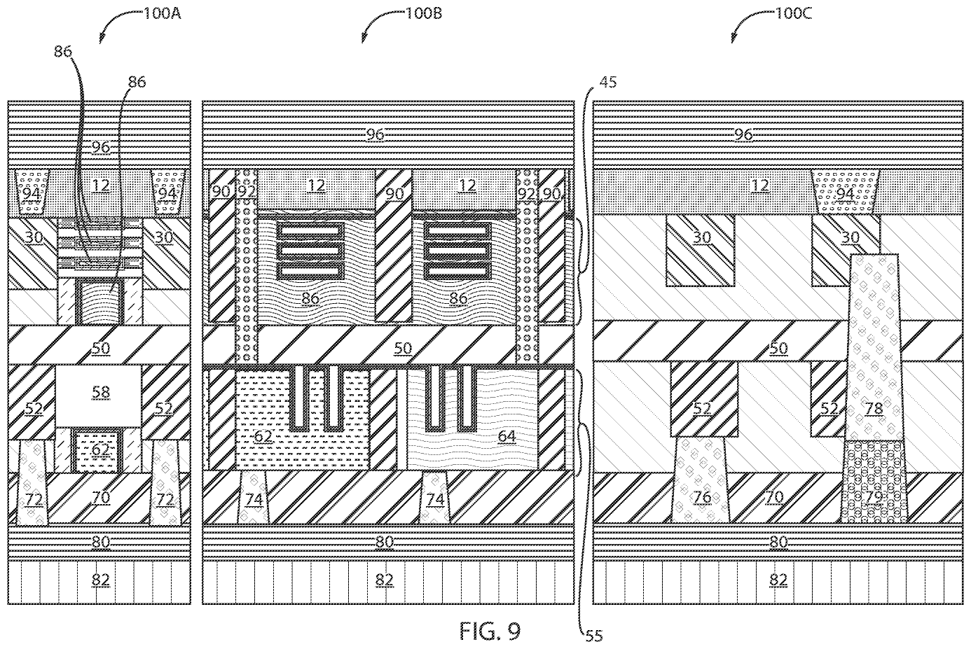

FIG. 9 is a cross-sectional view of the semiconductor structure of FIG. 8 where isolation walls are formed between the nanosheet stacks, contacts are formed to the replacement metal gates of the top FET and a backside power delivery network (BSPDN) is connected, in accordance with an embodiment of the present invention.

In various example embodiments, isolation walls 90 are formed between the nanosheet stacks in the bottom FET 45, contacts 92 are formed to the replacement metal gates or first and second WFMs 62, 64 of the top FET 55 and a BSPDN 96 is connected. Additionally, CA contacts 94 are formed in the BOX layer 12. The CA contacts 94 directly contact the top surface of the bottom S/D epi regions 30. Thus, the first contacts or CB contacts 74 are disposed from the first and second WFMs 62, 64 of the first FET (e.g., top FET 55) to the BEOL 80 and the second contacts or contacts 92 are disposed from the BSPDN 96 through the third WFM 86 of the second FET (e.g., bottom FET 45) to a top surface of the first and second WFMs 62, 64 of the first FET. This creates a direct connection between the BEOL 80 and the BSPDN 96.

The threshold voltage (Vt) is defined by a first WFM 62 (bottom left), the Vt is defined by a second WFM 64 (bottom right), the Vt is defined by a third WFM 86 (top left) and the Vt is defined by a third WFM 86 with a dipole material (top right). The dipole material is a metal impurity material distributed in the HfO₂ and the interfacial layer. Therefore, one region includes a dipole material. The dipole material includes, but is not limited to at least, La, Y, Al, Ga, Nb, Ti, Mg. Moreover, it is contemplated that any of the devices (nanosheets and/or fins) can include a dipole material with the WFM to define a Vt.

Moreover, a width of the contacts 92 can be equal to a width of the isolation walls 66 and equal to a width of the isolation walls 90. Sidewalls of the contacts 92 can directly contact sidewalls of the isolation walls 90. A length of the contacts 92 is greater than a length of the isolation walls 66, 90.

The structure 100A depicts the nanosheets stacks in the X direction.

The structure 100B illustrates the nanosheets stacks in the bottom FET 45 and the fins in the top FET 55.

The structure 100C illustrates the top S/D epi regions 52 and the bottom S/D epi regions 30.

Moreover, a first set of fins 58 (e.g., left-hand side surrounded by the first WFM 62) in the top FET 55 is vertically aligned with a first nanosheet stack (e.g., left-hand side) in the bottom FET 45. A second set of fins 58 (e.g., right-hand side surrounded by the second WFM 64) in the top FET 55 is vertically aligned with a second nanosheet stack (e.g., right-hand side) in the bottom FET 45.

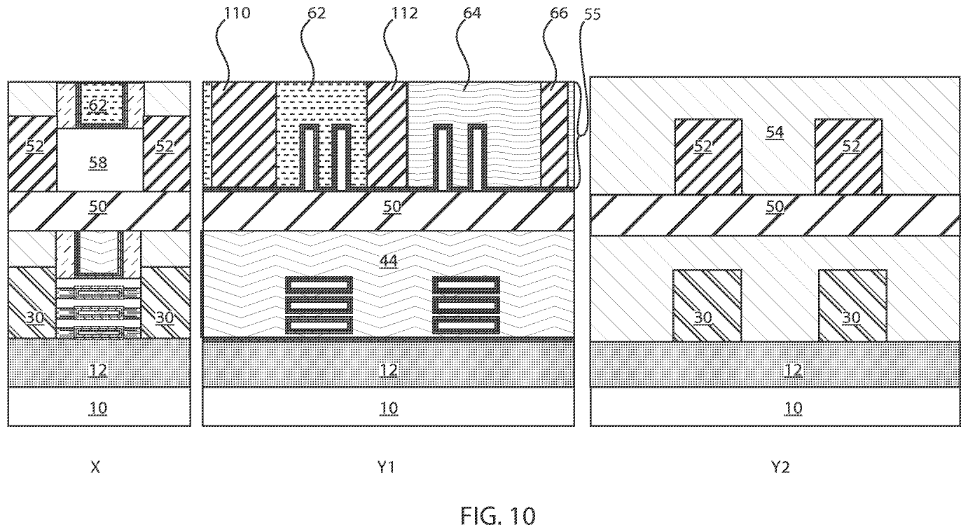

FIG. 10 is a cross-sectional view of a semiconductor structure where thick isolation walls are formed to separate fins of the top FET and the dummy gates of the top FET are replaced with different replacement metal gates, in accordance with another embodiment of the present invention.

In various example embodiments, FIG. 10 is similar to FIG. 5. However, in contrast to FIG. 5, thick isolation walls 110, 112 are formed on opposed ends of a first set of fins such that thick isolation wall 112 separates the first WFM 62 from the second WFM 64 in the Y1 direction in the top FET 55.

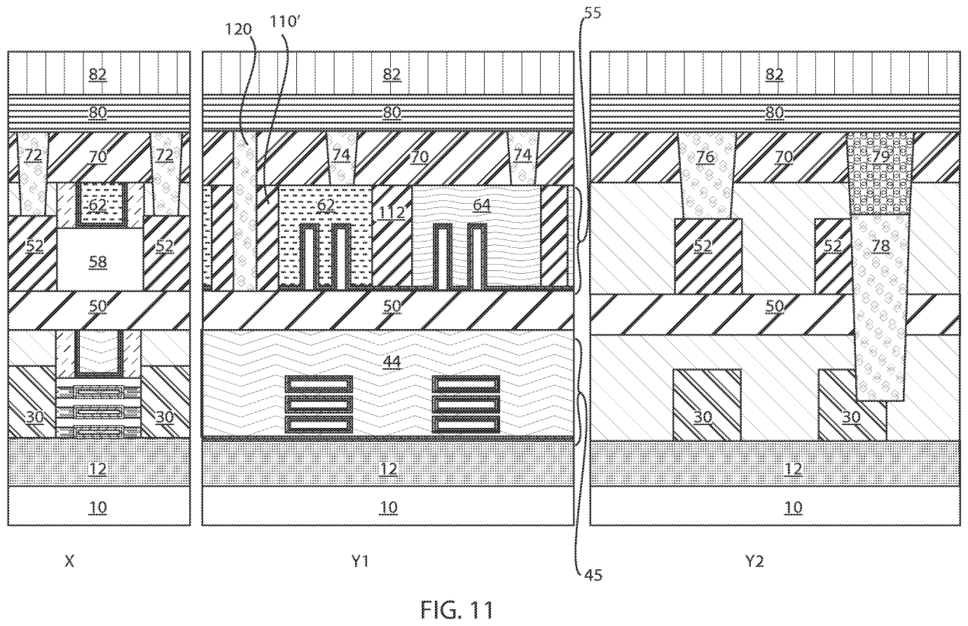

FIG. 11 is a cross-sectional view of the semiconductor structure of FIG. 10 where contacts are formed to the replacement metal gates of the top FET, BEOL processing takes place, and a carrier wafer is bonded to the BEOL, in accordance with an embodiment of the present invention.

In various example embodiments, contacts are formed to the replacement metal gates of the top FET, the BEOL 80 takes place, and a carrier wafer 82 is bonded to the BEOL 80.

In particular, contacts 74 are formed to the top surface of the first WFM 62 and the second WFM 64. The contacts 74 are referred to as CB contacts. CB contacts are gate contacts. Contacts 72 are formed to the top surface of the top S/D epi regions 52 in the X direction. The contacts 72 are referred to as CA contacts. CA contacts are S/D contacts. Contact 76 is formed to the top surface of the top S/D epi region 52 in the Y2 direction. The contact 76 is also a CA contact or S/D contact. Additionally, contact 78 is formed through the bonding oxide 50 to the bottom S/D epi region 30. A dielectric cap 79 is formed over the contact 78. The BEOL 80 directly contacts the top surfaces of the CA contacts 72, 76 and the CB contacts 74. A carrier wafer 82 is then bonded to the BEOL 80.

Additionally, in contrast to FIG. 6, in the Y1 direction, another CB contact 120 extends through the isolation wall 110. The isolation wall 110 is now designated as isolation wall 110′. The CB contact 120 directly contacts the bonding oxide 50. The CB contact 120 extends entirely through the isolation all 110.

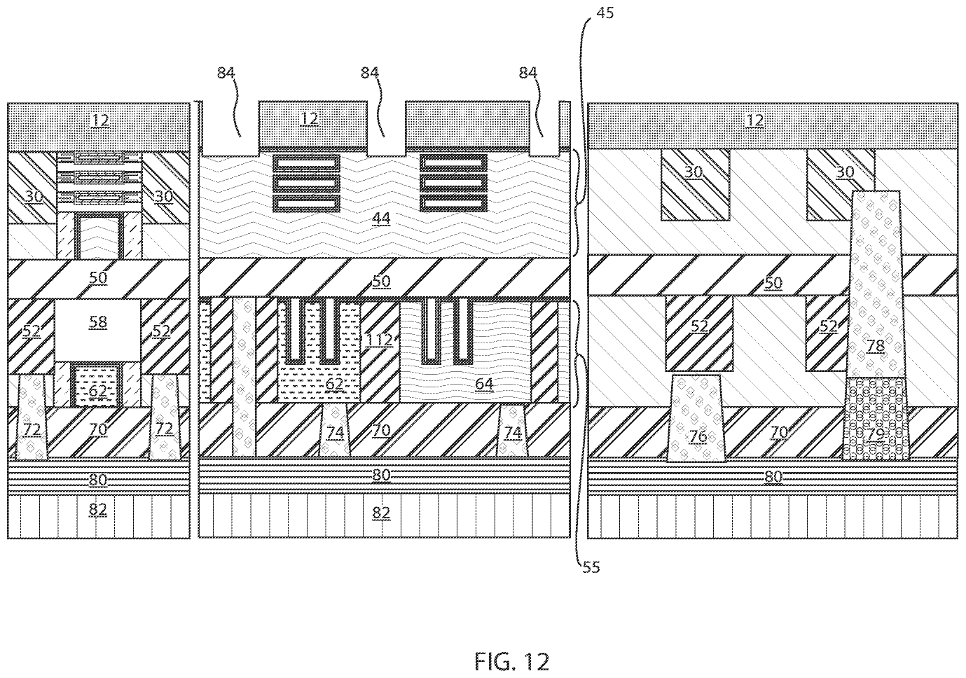

FIG. 12 is a cross-sectional view of the semiconductor structure of FIG. 11 where the structure is flipped and openings are made to the dummy gate of the bottom FET, in accordance with an embodiment of the present invention.

In various example embodiments, the structure is flipped and openings 84 are made to the dummy gate 44 of the bottom FET 45.

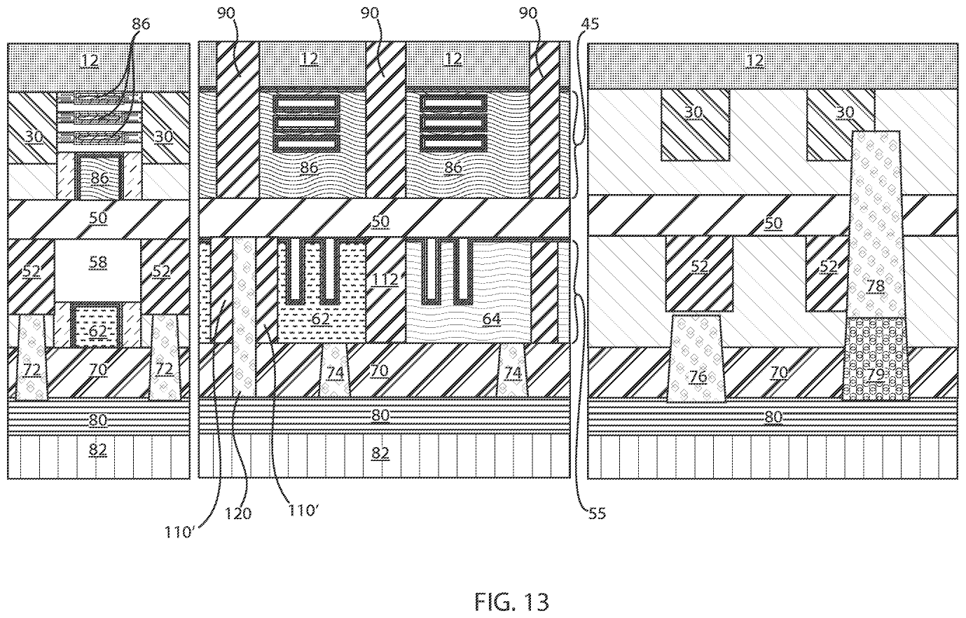

FIG. 13 is a cross-sectional view of the semiconductor structure of FIG. 12 where the dummy gate is selectively removed, a replacement metal gate is deposited in the bottom FET, and thick isolation walls are formed in the bottom FET to separate the nanosheet stacks, in accordance with an embodiment of the present invention.

In various example embodiments, the dummy gate 44 is selectively removed, a replacement metal gate or WFM 86 is deposited in the bottom FET 45, and thick isolation walls are formed in the bottom FET 45 to separate the nanosheet stacks. The thick isolation walls extend to a top surface of the bonding oxide 50. The WFM 86 can be referred as to as a third WFM. This configuration thus results in 3 different WFMs being present in the structure, where each of the WFMs can be composed of a different material.

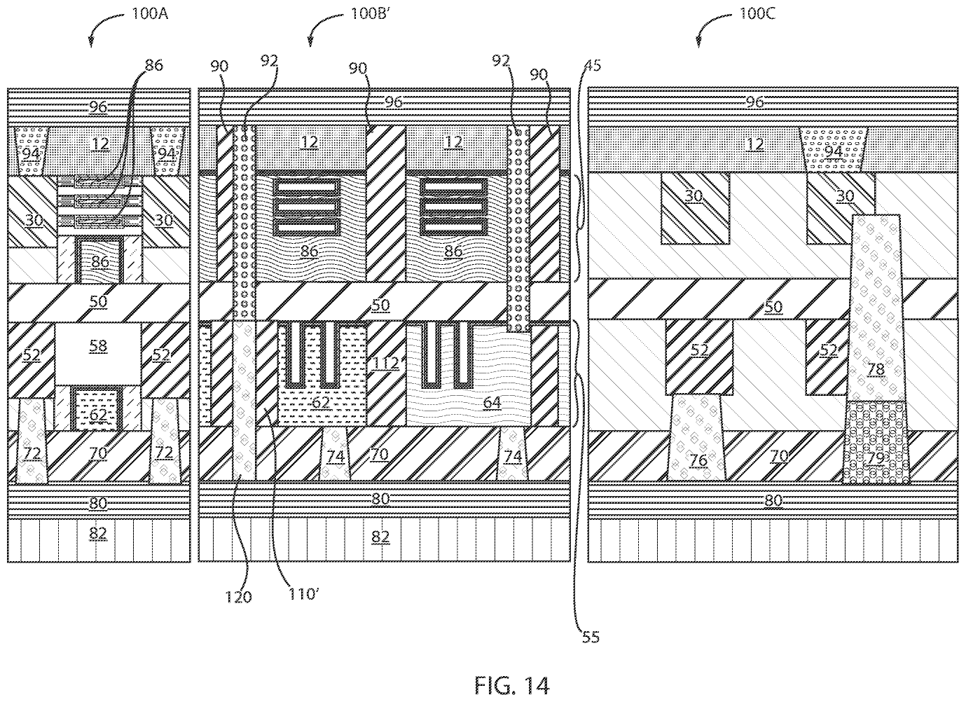

FIG. 14 is a cross-sectional view of the semiconductor structure of FIG. 13 where contacts are formed to the replacement metal gates of the top FET and a backside power delivery network (BSPDN) is connected, in accordance with another embodiment of the present invention.

In various example embodiments, contacts 92 are formed to the replacement metal gates or first and second WFMs 62, 64 of the top FET 55 and a BSPDN 96 is connected. One contact 92 directly contacts the CB contact 120 in the Y1 direction.

The structure 100B′ depicts the CB contact 120 extending through the isolation wall 110′ to the BEOL 80.

A first set of fins 58 (e.g., left-hand side surrounded by the first WFM 62) in the top FET 55 is vertically aligned with a first nanosheet stack (e.g., left-hand side) in the bottom FET 45. A second set of fins 58 (e.g., right-hand side surrounded by the second WFM 64) in the top FET 55 is vertically aligned with a second nanosheet stack (e.g., right-hand side) in the bottom FET 45.

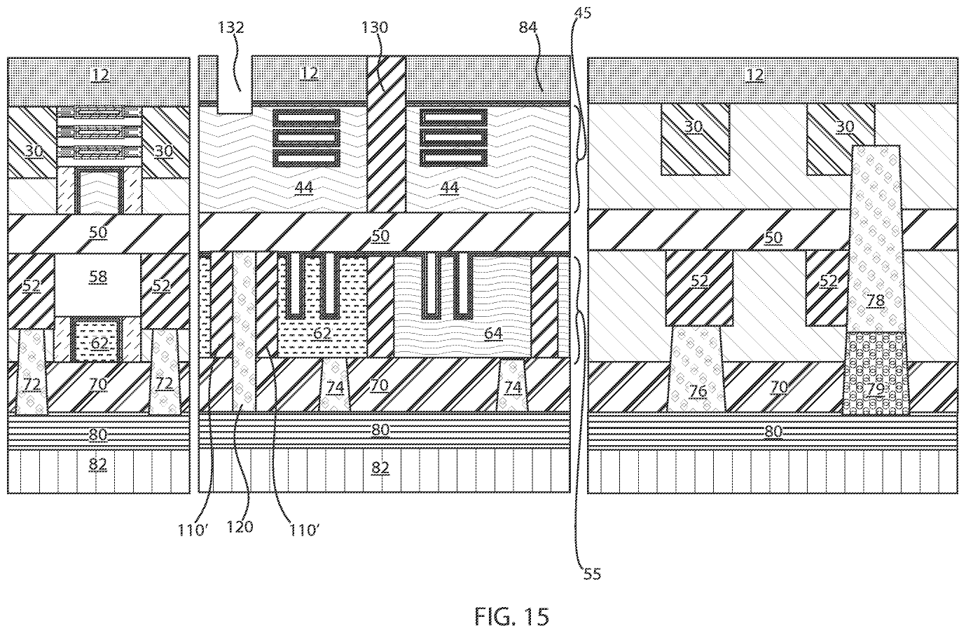

FIG. 15 is a cross-sectional view of a semiconductor structure similar to FIGS. 10 and 11, where the structure is flipped, a single thick isolation wall is formed through the dummy gate of the bottom FET, and a single opening is made to the dummy gate of the bottom FET, in accordance with another embodiment of the present invention.

In various example embodiments, a semiconductor structure similar to FIGS. 10 and 11 is presented, where the structure is flipped, a single thick isolation wall 130 is formed through the dummy gate 44 of the bottom FET 45, and a single opening 132 is made to the dummy gate 44 of the bottom FET 45. The single opening 132 is vertically aligned with the CB contact 120 extending through the isolation wall 110′ in the top FET 55. The single isolation wall 130 in the bottom FET 45 is thicker than the isolation walls 66 of the top FET 55.

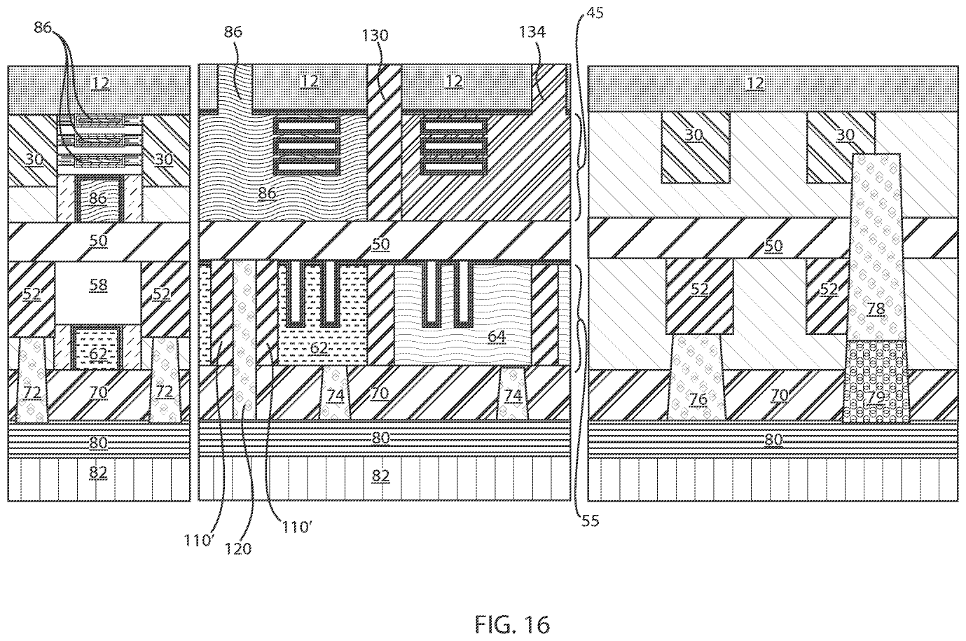

FIG. 16 is a cross-sectional view of the semiconductor structure of FIG. 15 where the dummy gate is selectively removed, and different replacement metal gate are formed on opposed ends of the single thick isolation wall, in accordance with an embodiment of the present invention.

In various example embodiments, a first portion of the dummy gate 44 is selectively removed and replaced with a WFM 86. Then the second portion of the dummy gate 44 is selectively removed and replaced with a WFM 134. The single isolation wall 130 separates the WFM 86 from the WFM 134. The WFM 86 can be referred to as a third WFM and the WFM 134 can be referred to as a fourth WFM.

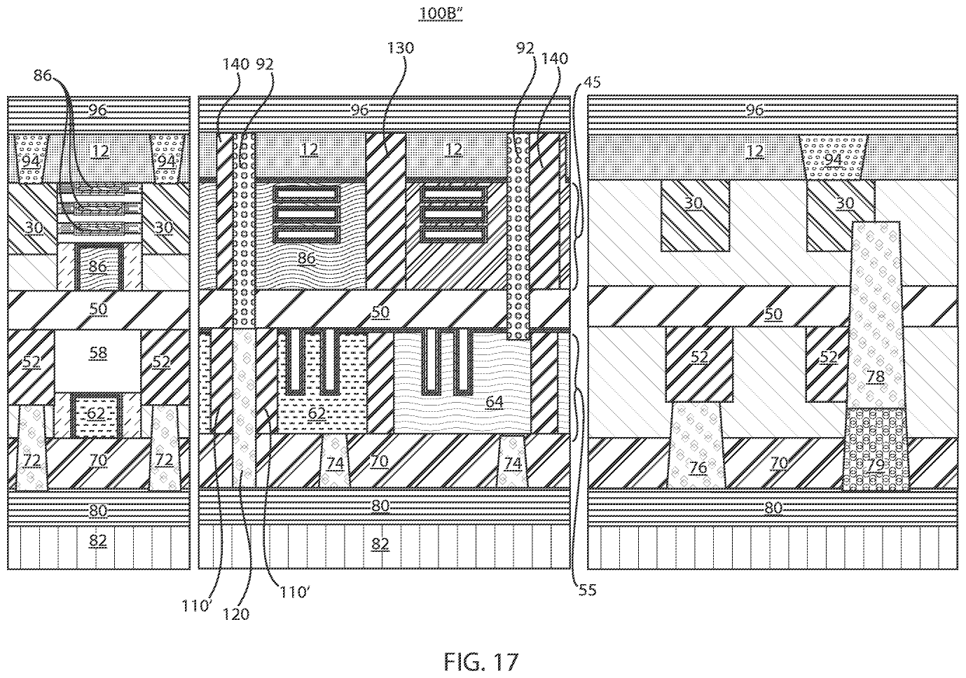

FIG. 17 is a cross-sectional view of the semiconductor structure of FIG. 16 where two more isolation walls are formed on opposed ends of the first isolation wall, contacts are formed to the replacement metal gates of the top FET and a backside power delivery network (BSPDN) is connected, in accordance with an embodiment of the present invention.

In various example embodiments, two more isolation walls 140 are formed on opposed ends of the first isolation wall 130, contacts 92 are formed through the replacement metal gates or third and fourth WFMs 86, 134 of the bottom FET 45 and a BSPDN 96 is connected. Additionally, CA contacts 94 are formed in the BOX layer 12. The CA contacts 94 directly contact the top surface of the bottom S/D epi regions 30. The isolation walls 140 directly contact sidewalls of the contacts 92. One contact 92 directly contacts the CB contact 120 in the Y1 direction. This configuration results in 4 different WFMs being present in the structure, where each of the WFMs can be composed of a different material.

The structure 100B″ depicts the CB contact 120 extending through the isolation wall 110′ to the BEOL 80.

A first set of fins 58 (e.g., left-hand side surrounded by the first WFM 62) in the top FET 55 is vertically aligned with a first nanosheet stack (e.g., left-hand side surrounded by the third WFM 86) in the bottom FET 45. A second set of fins 58 (e.g., right-hand side surrounded by the second WFM 64) in the top FET 55 is vertically aligned with a second nanosheet stack (e.g., right-hand side surrounded by the fourth WFM 134) in the bottom FET 45.

The threshold voltage (Vt) is defined by a first WFM 62 (bottom left), the Vt is defined by a second WFM 64 (bottom right), the Vt is defined by a third WFM 86 (top left) and the Vt is defined by a fourth WFM 134 (top right). No dipole material is present in this embodiment.

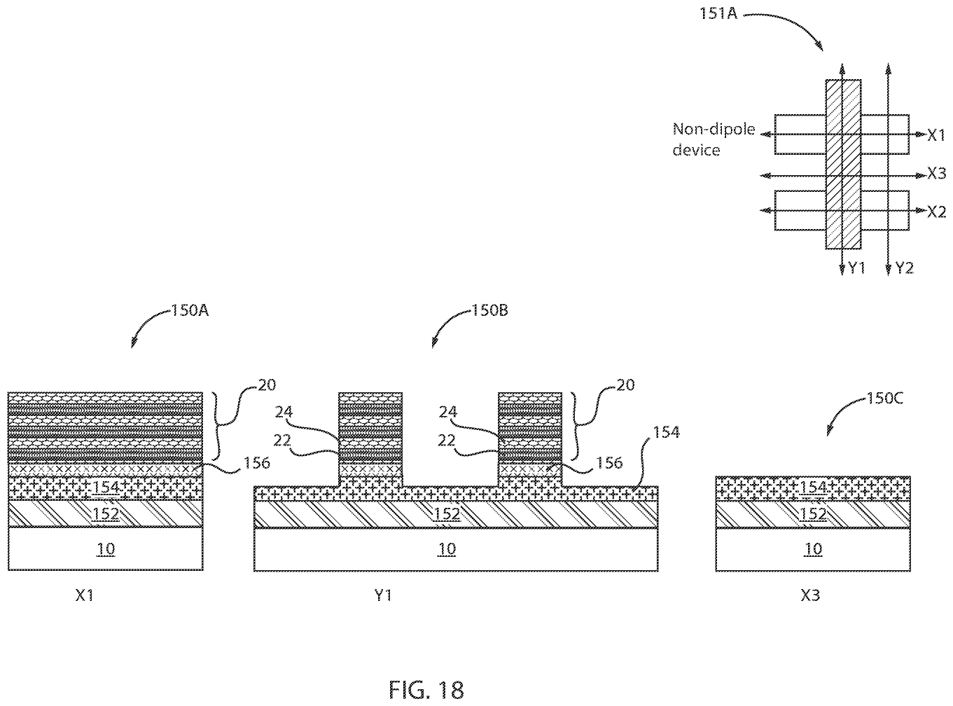

FIG. 18 is a cross-sectional view of a semiconductor structure including a nanosheet stack formed over a substrate, where an etch stop layer and an isolation layer including SiGe with a high concentration of Ge are formed between the substrate and the nanosheet stack, in accordance with another embodiment of the present invention.

In various example embodiments, a nanosheet stack 20 is formed over a substrate 10, where an etch stop layer 152 and an isolation layer 156 including SiGe with a high concentration of Ge are formed between the substrate 10 and the nanosheet stack 20. The etch stop layer 152 is formed directly over the substrate 10. A Si layer 154 is formed directly over the etch stop layer 152. The isolation layer 156 is formed directly over the Si layer 154. The nanosheet stack 20 is formed directly over the isolation layer 156.

The structure 150A depicts the nanosheet stack in the X1 direction as shown in top view 151A.

The structure 150B depicts the nanosheet stack in the Y1 direction as shown in top view 151A.

The structure 150C depicts the nanosheet stack in the X3 direction as shown in top view 151A.

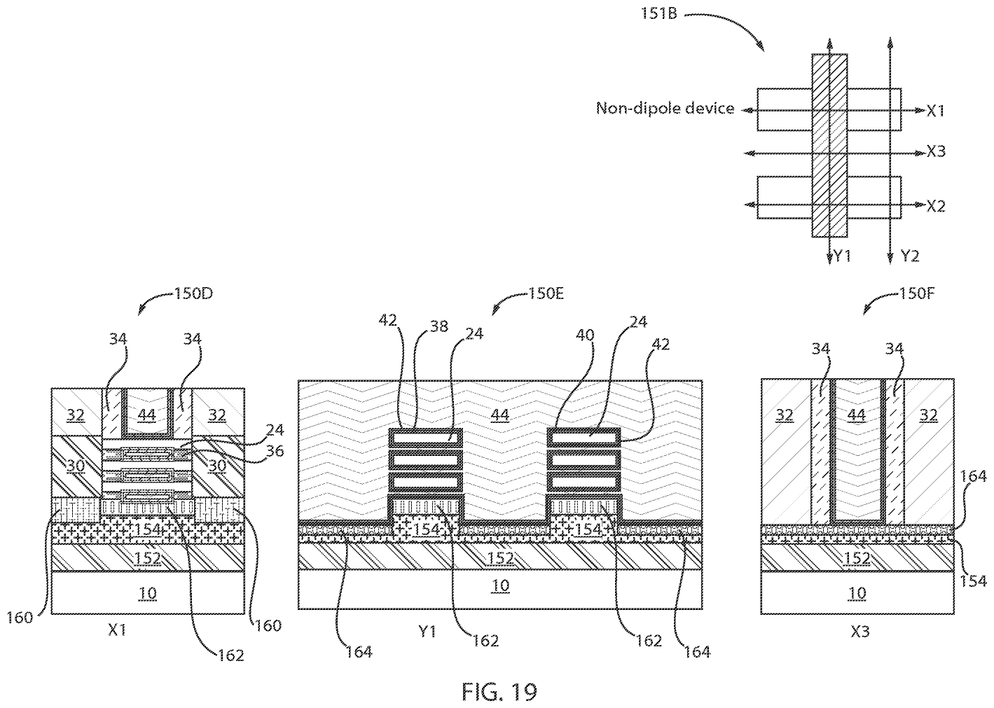

FIG. 19 is a cross-sectional view of the semiconductor structure of FIG. 18 where source/drain epi regions, an interlayer dielectric (ILD), spacers, inner spacers, and a dummy gate are formed/deposited, and where the sacrificial layers of the nanosheet stack are removed to complete the bottom FET having nanosheet stacks, in accordance with an embodiment of the present invention.

In various example embodiments, source/drain (S/D) regions 160 are formed adjacent a bottom dielectric isolation (BDI) 162. The bottom S/D epi regions 30 are also formed over the S/D regions 160. An ILD 32 is formed over the bottom S/D epi regions 30. Spacers 34 are formed adjacent the ILD 32. The sacrificial layers (e.g., SiGe layers) of the nanosheet stacks 20 are selectively removed and inner spacers 36 are formed. A first interfacial layer (IL) 38 surrounds the remaining Si layers 24 of one nanosheet stack 20. A second interfacial layer (IL) surrounds the remaining Si layers 24 of another nanosheet stack 20. An HK dielectric layer 42 surrounds the ILs 38, 40. A dummy gate 44 is then deposited to surround the nanosheet stacks 20. The bottom FET 45 is complete.

The structure 150D is a cross-section along axis X1 as shown in the top view 151B.

The structure 150E is a cross-section along axis Y1 as shown in the top view 151B. In the structure 150E, both the first and second ILs 38, 40 are visible.

The structure 150F is a cross-section along axis X2 as shown in the top view 7B.

In the structures 150E, 150F, STI regions 164 are also visible. The STI regions 164 rest within the recessed portions or trenches of the Si layer 154.

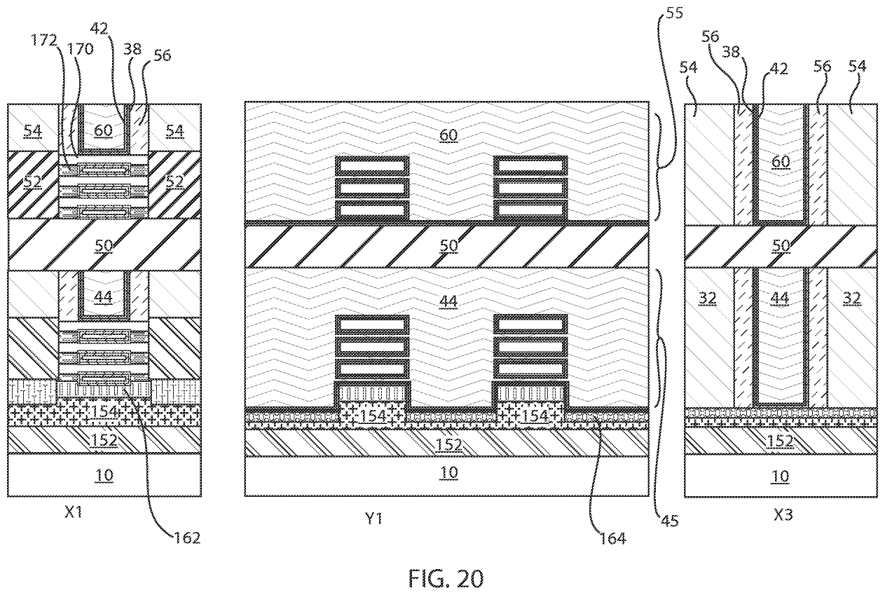

FIG. 20 is a cross-sectional view of the semiconductor structure of FIG. 19 where a top FET is formed including nanosheet stacks, the top FET formed over the bottom FET, in accordance with an embodiment of the present invention.

In various example embodiments, a top FET 55 is formed including nanosheet stacks, the top FET 55 formed over the bottom FET 45. A bonding oxide 50 is deposited over the bottom FET 45. The top FET 55 is formed over the bonding oxide 50. The top FET 55 includes top S/D epi regions 52. An ILD 54 is formed over the top S/D epi regions 52. Spacers 56 are formed adjacent the ILD 54. A first interfacial layer (IL) 38 surrounds one nanosheet stack and a second IL 40 surrounds another nanosheet stack. A HK dielectric layer 42 surrounds the ILs 38, 40. A dummy gate 60 is then deposited. The top nanosheet stacks include Si layers 170 and inner spacers 172.

Therefore, the bottom FET 45 includes nanosheet stacks, and the top FET 55 includes nanosheet stacks. The bonding oxide 50 separates the bottom FET 45 from the top FET 55.

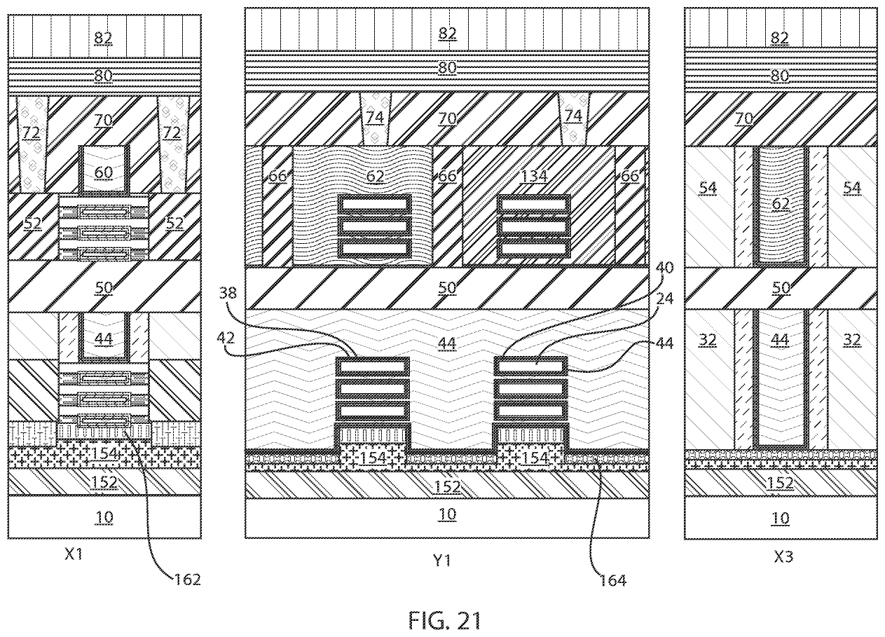

FIG. 21 is a cross-sectional view of the semiconductor structure of FIG. 20 where the dummy gates of the top FET are replaced with replacement metal gates and where contacts are formed to the replacement metal gates, back-end-of-line (BEOL) processing takes place, and a carrier wafer is bonded to the BEOL, in accordance with an embodiment of the present invention.

In various example embodiments, isolation walls 66 are formed, the dummy gates of the top FET 55 are replaced with replacement metal gates or WFMs 62, 134 and contacts 74 are formed to the WFMs 62, 134 in the Y1 direction. An ILD 70 is formed over the WFMs 62, 134. The BEOL 80 takes place and a carrier wafer 82 is bonded to the BEOL 80.

Contacts 74 are formed to the top surface of the first WFM 62 and the second WFM 134. The contacts 74 are referred to as CB contacts. CB contacts are gate contacts. Contacts 72 are formed to the top surface of the top S/D epi regions 52 in the X1 direction. The contacts 72 are referred to as CA contacts. CA contacts are S/D contacts.

The BEOL 80 directly contacts the top surfaces of the CA contacts 72 and the CB contacts 74. A carrier wafer 82 is then bonded to the BEOL 80.

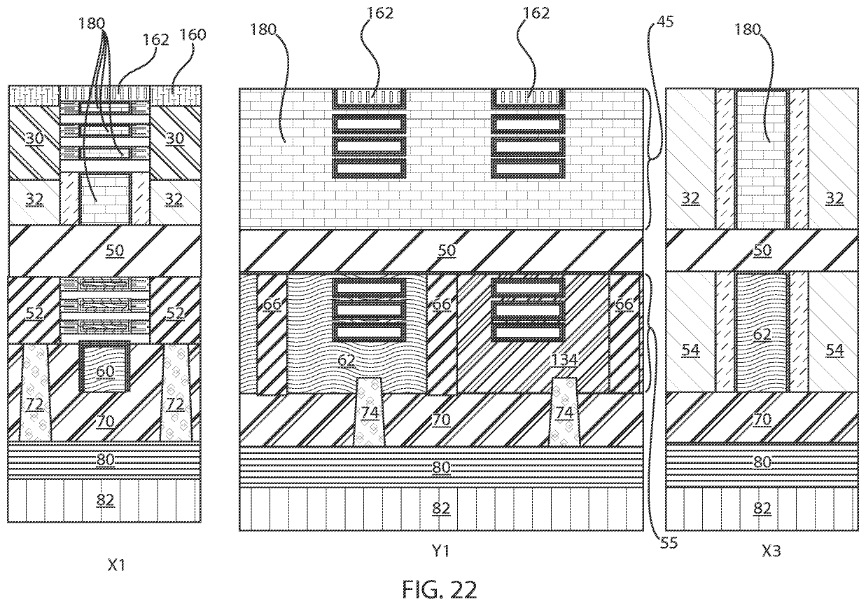

FIG. 22 is a cross-sectional view of the semiconductor structure of FIG. 21 where the structure is flipped, the substrate and etch stop layer are removed, the dummy gate is removed, and a replacement metal gate is deposited around the bottom nanosheet stacks, in accordance with an embodiment of the present invention.

In various example embodiments, the structure is flipped, the substrate 10 and etch stop layer 152 are removed, the STI regions 164 are removed, the dummy gate 60 is selectively removed, and a replacement metal gate or WFM 180 is deposited around the bottom nanosheet stacks of the bottom FET 45. The BDI regions 162 remain intact. The WFM 62 can be referred to as a first WFM, the WFM 134 can be referred to as a second WFM, and the WFM 180 can be referred to as a third WFM. This configuration thus results in 3 different WFMs being present in the structure, where each of the WFMs can be composed of a different material.

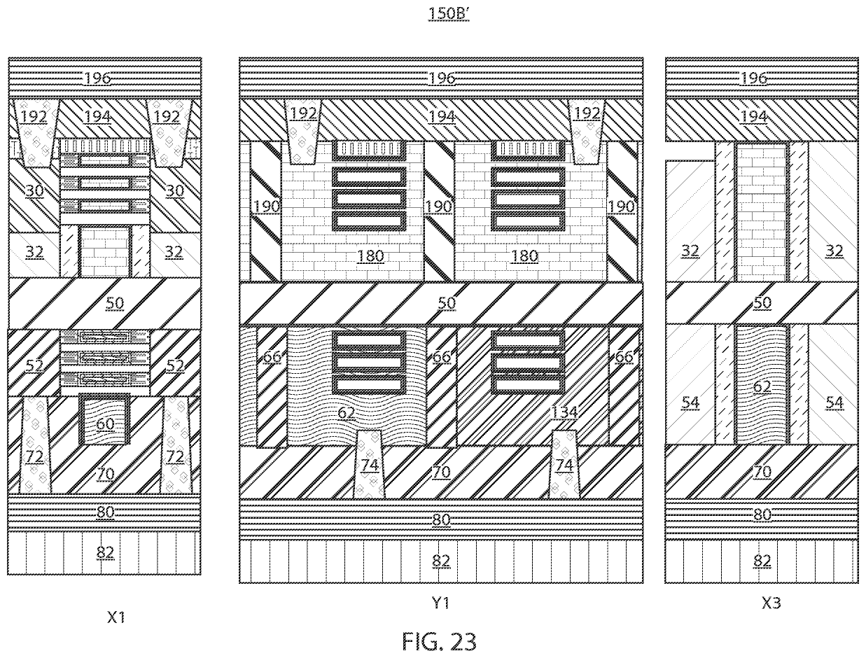

FIG. 23 is a cross-sectional view of the semiconductor structure of FIG. 22 where isolation walls are formed to isolate the bottom nanosheet stacks, contacts are formed to the replacement metal gate of the bottom FET, and a backside power delivery network (BSPDN) is connected, in accordance with an embodiment of the present invention.

In various example embodiments, isolation walls 190 are formed to isolate the bottom nanosheet stacks of the bottom FET 45, an ILD 194 is deposited, contacts 192 are formed to the WFM 180 of the bottom FET 45, and a BSPDN 196 is connected.

A first nanosheet stack (e.g., left-hand side surrounded by the first WFM 62) in the top FET 55 is vertically aligned with a first nanosheet stack (e.g., left-hand side surrounded by the third WFM 180) in the bottom FET 45. A second nanosheet stack (e.g., right-hand side surrounded by the second WFM 134) in the top FET 55 is vertically aligned with a second nanosheet stack (e.g., right-hand side surrounded by the third WFM 180) in the bottom FET 45. The structure 150B′ depicts this relationship between nanosheet stacks of the bottom FET 45 and the top FET 55.

The threshold voltage (Vt) is defined by a first WFM 62 (bottom left), the Vt is defined by a second WFM 134 (bottom right) with a dipole material, the Vt is defined by a third WFM 180 (top left) and the Vt is defined by a third WFM 180 (top right) with a dipole material. The dipole material is a metal impurity material distributed in the HfO₂ and the interfacial layer. Therefore, in contrast to FIG. 9, two regions in FIG. 23 include the dipole material (top right and bottom right). The dipole material includes, but is not limited to at least, La, Y, Al, Ga, Nb, Ti, Mg. Moreover, it is contemplated that any of the devices (nanosheets and/or fins) can include a dipole material with the WFM to define a Vt.

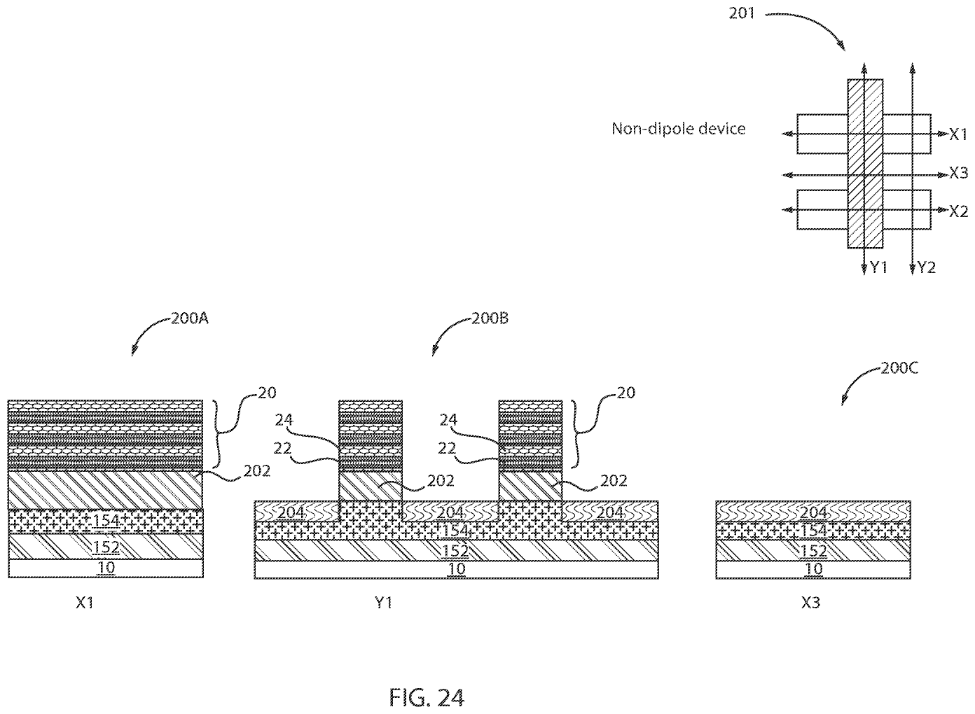

FIG. 24 is a cross-sectional view of a semiconductor structure including a nanosheet stack formed over a substrate, where an etch stop layer and a SiGe layer with a low concentration of Ge are formed between the substrate and the nanosheet stack, in accordance with another embodiment of the present invention.

In various example embodiments, a nanosheet stack 20 is formed over a substrate 10, where an etch stop layer 152 and an isolation layer 202 including SiGe with a low concentration of Ge are formed between the substrate 10 and the nanosheet stack 20. The etch stop layer 152 is formed directly over the substrate 10. A Si layer 154 is formed directly over the etch stop layer 152. The isolation layer 202 is formed directly over the Si layer 154. The nanosheet stack is formed directly over the isolation layer 202.

The structure 200A depicts the nanosheet stack in the X1 direction as shown in top view 201.

The structure 200B depicts the nanosheet stack in the Y1 direction as shown in top view 201. The structure 200B also depicts STI regions 204 formed in the trenches of the Si layer 154.

The structure 200C depicts the nanosheet stack in the X3 direction as shown in top view 201.

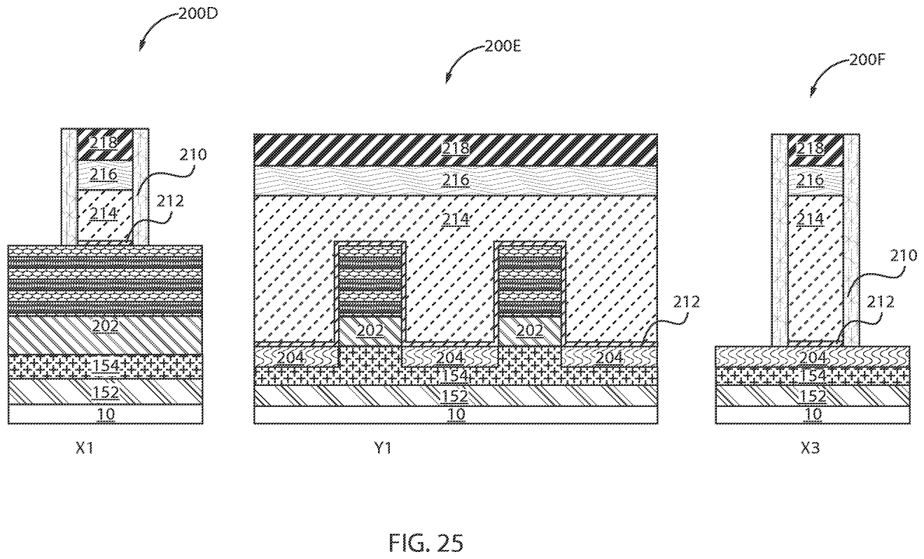

FIG. 25 is a cross-sectional view of the semiconductor structure of FIG. 24 where a dummy gate is deposited and the nanosheet stack is recessed to form fins, in accordance with an embodiment of the present invention.

In various example embodiments, a dielectric liner 212, a dummy gate 214, an ILD 216, and a hardmask 218 are deposited and the nanosheet stack 20 is recessed to form fins. Spacers 210 are formed on opposed ends of the dummy gate 214, the ILD 216, and the hardmask 218.

The structure 200D depicts the nanosheet stack in the X1 direction of the top view 201.

The structure 200E depicts the nanosheet stack in the Y1 direction of the top view 201.

The structure 200F depicts the nanosheet stack in the X3 direction of the top view 201.

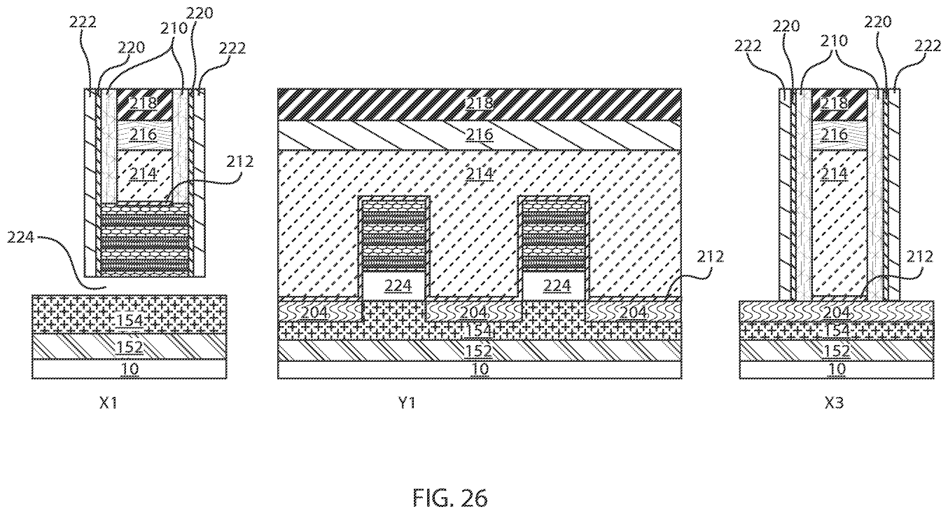

FIG. 26 is a cross-sectional view of the semiconductor structure of FIG. 25 where an oxide layer and a nitride layer are deposited, and the SiGe layer with a low concentration of Ge is selectively removed, in accordance with an embodiment of the present invention.

In various example embodiments, an oxide layer 220 and a nitride layer 222 are deposited, and the SiGe layer with a low concentration of Ge is selectively removed to create gaps 224 depicted in the X1 and Y1 directions.

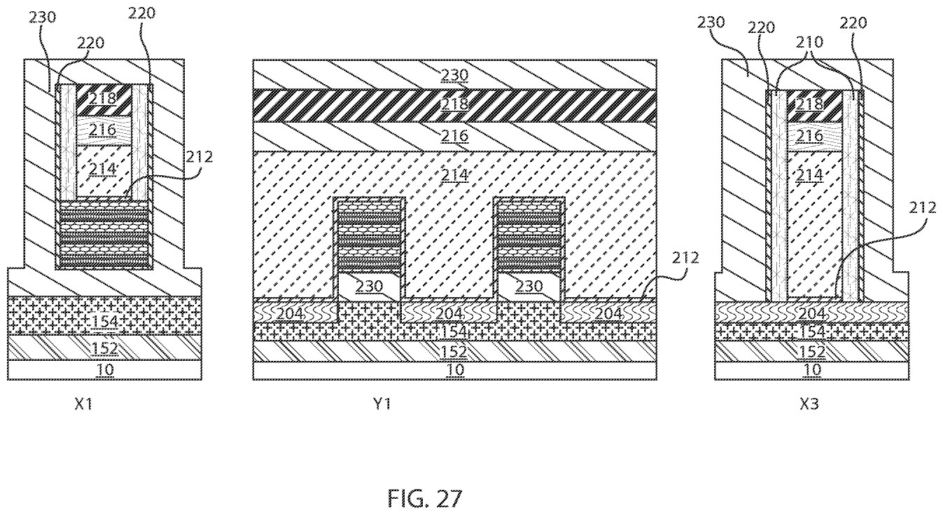

FIG. 27 is a cross-sectional view of the semiconductor structure of FIG. 26 where an etch stop layer is deposited, in accordance with an embodiment of the present invention.

In various example embodiments, an etch stop layer 230 is deposited. The etch stop layer 230 can be a dielectric.

The dielectric of the etch stop layer 230 can include, but is not limited to, SiN, SiOCN, SiOC, SiBCN, SO₂, or ultra-low-k (ULK) materials, such as, for example, porous silicates, carbon doped oxides, silicon dioxides, silicon nitrides, silicon oxynitrides, carbon-doped silicon oxide (SiCOH) and porous variants thereof, silsesquioxanes, siloxanes, or other dielectric materials having, for example, a dielectric constant in the range of about 2 to about 10.

In some embodiments, the dielectric of the etch stop layer 230 can be conformally deposited using atomic layer deposition (ALD) or, chemical vapor deposition (CVD). Variations of CVD processes suitable for forming the dielectric layer 14 include, but are not limited to, Atmospheric Pressure CVD (APCVD), Low Pressure CVD (LPCVD) and Plasma Enhanced CVD (PECVD), Metal-Organic CVD (MOCVD) and combinations thereof can also be employed.

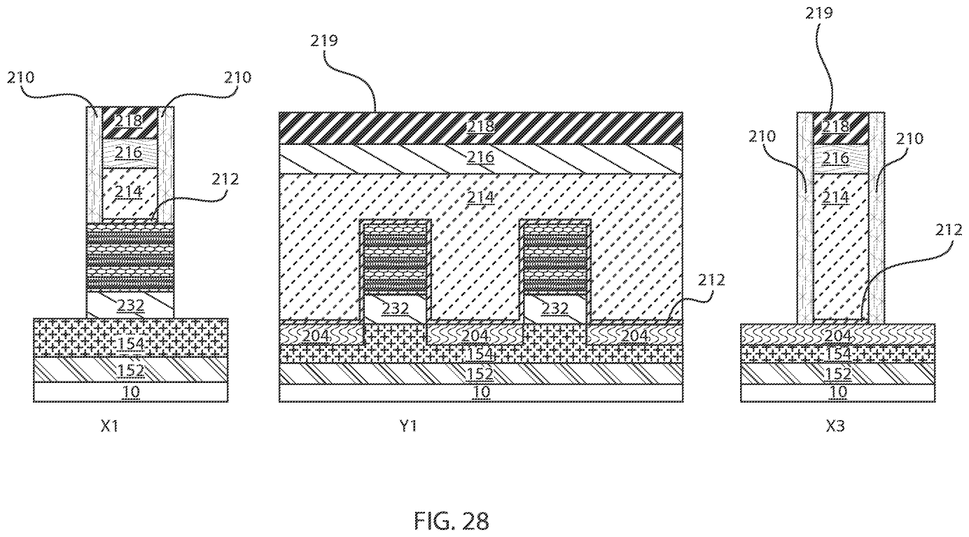

FIG. 28 is a cross-sectional view of the semiconductor structure of FIG. 27 where the etch stop layer is etched back such that etch stop layer portions remain directly under the nanosheets stacks of the bottom FET, in accordance with an embodiment of the present invention.

In various example embodiments, the etch stop layer 230 is etched back such that etch stop layer portions 232 remain directly under the nanosheets stacks 20 of the bottom FET. The etch back results in the exposure of a top surface 219 of the hardmask 218.

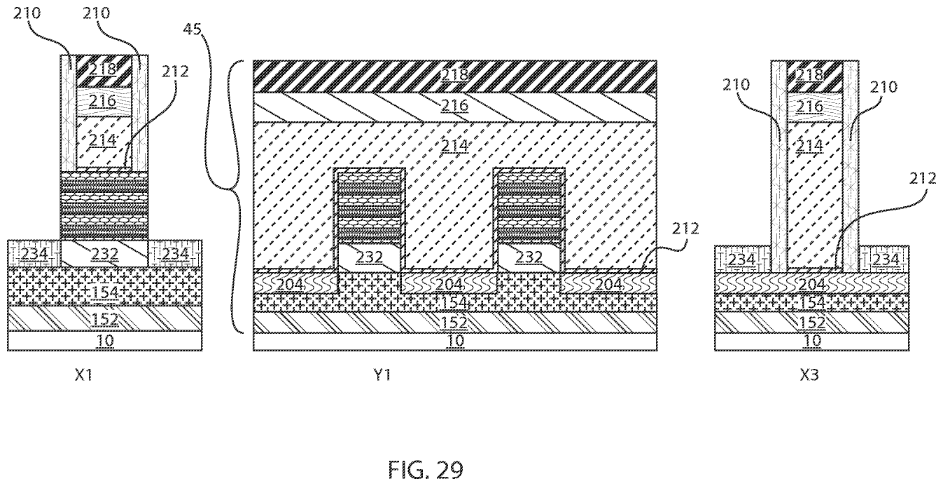

FIG. 29 is a cross-sectional view of the semiconductor structure of FIG. 28 where an oxide layer is deposited to complete the bottom FET, in accordance with an embodiment of the present invention.

In various example embodiments, an oxide layer 234 is deposited to complete the bottom FET 45. The oxide layer 234 directly contacts the etch stop layer portions 232. The oxide layer 234 is horizontally aligned with the etch stop layer portions 232 in the X1 direction.

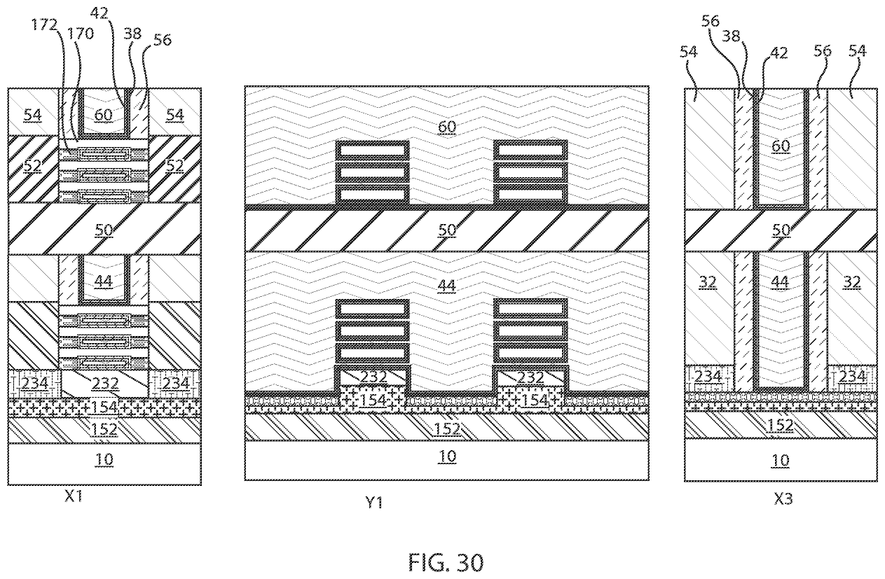

FIG. 30 is a cross-sectional view of the semiconductor structure of FIG. 29 where the top FET is formed over the bottom FET, in accordance with an embodiment of the present invention.

In various example embodiments, the top FET 55 is formed over the bottom FET 45 similarly to FIG. 20 discussed above.

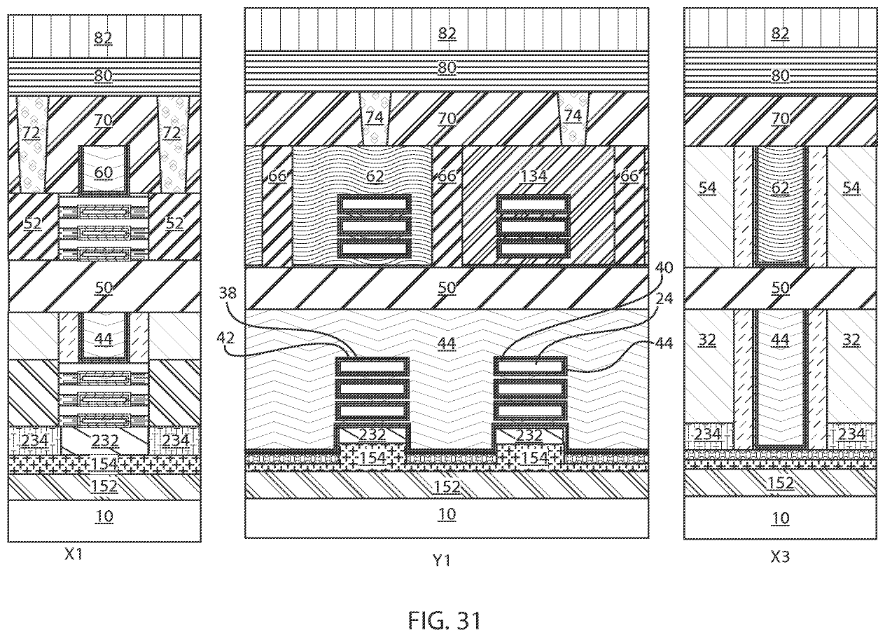

FIG. 31 is a cross-sectional view of the semiconductor structure of FIG. 30 where the dummy gates of the top FET are replaced with different replacement metal gates, contacts are formed to the replacement metal gates, BEOL processing is performed, and wafer boding takes place, in accordance with an embodiment of the present invention.

In various example embodiments, the dummy gates 60 of the top FET 55 are replaced with different replacement metal gates or WFMs 62, 134, contacts 72, 74 are formed, BEOL 80 is performed, and wafer bonding 82 takes place similarly to FIG. 21 discussed above.

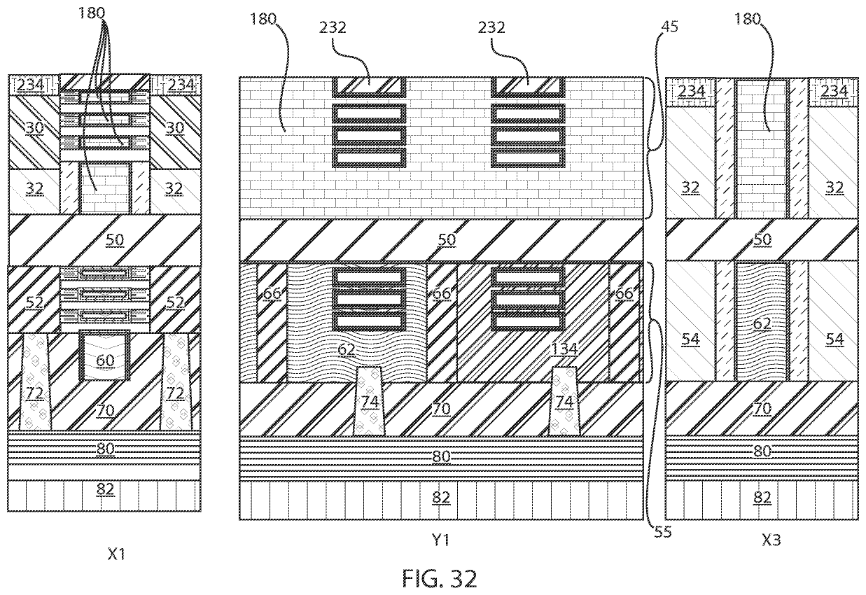

FIG. 32 is a cross-sectional view of the semiconductor structure of FIG. 31 where the structure is flipped, the substrate and etch stop layer are removed to expose the etch stop layer portions directly underneath the nanosheet stacks, the dummy gate is selectively removed, and a replacement metal gate is deposited around the bottom nanosheet stacks, in accordance with an embodiment of the present invention.

In various example embodiments, the structure is flipped, the substrate 10 and etch stop layer 152 are removed to expose the etch stop layer portions 232 directly underneath the nanosheet stacks, the dummy gate 214 is selectively removed, and a replacement metal gate or WFM 180 is deposited around the bottom nanosheet stacks of the bottom FET 45. These processing steps are similar to the processing steps of FIG. 22 discussed above. This configuration results in 3 different WFMs being present in the structure, where each of the WFMs can be composed of a different material.

A first nanosheet stack (e.g., left-hand side surrounded by the first WFM 62) in the top FET 55 is vertically aligned with a first nanosheet stack (e.g., left-hand side surrounded by the third WFM 180) in the bottom FET 45. A second nanosheet stack (e.g., right-hand side surrounded by the second WFM 134 and a dipole material) in the top FET 55 is vertically aligned with a second nanosheet stack (e.g., right-hand side surrounded by the third WFM 180 and a dipole material) in the bottom FET 45.

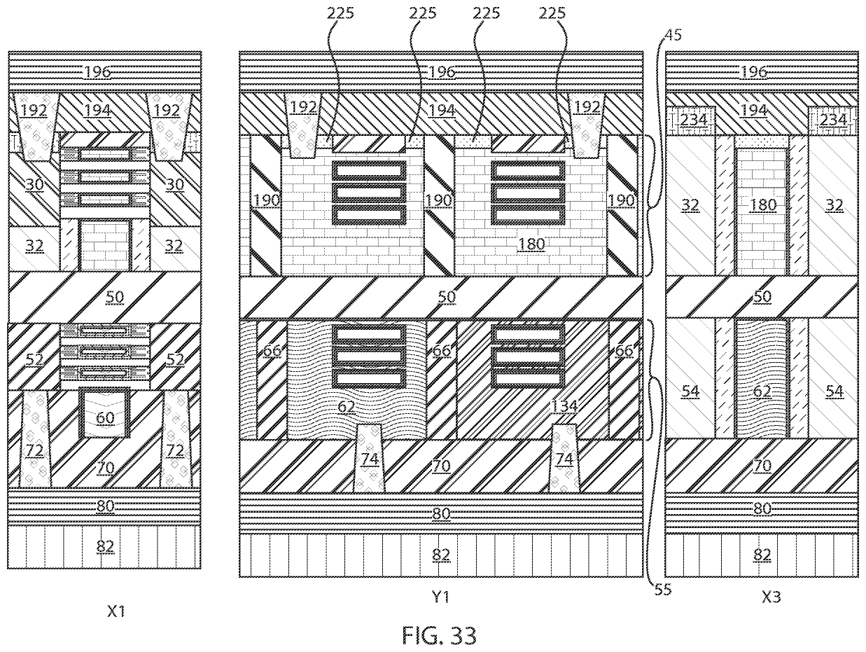

FIG. 33 is a cross-sectional view of the semiconductor structure of FIG. 32 where isolation walls are formed within the bottom FET, self-aligned contacts (SACs) are formed and a backside power delivery network (BSPDN) is connected, in accordance with an embodiment of the present invention.

In various example embodiments, isolation walls 190 are formed within the bottom FET 45, self-aligned contacts (SAC) 225 adjacent the etch stop layer portions 232 are formed, the ILD 194 is formed, contacts 192 are formed to the SACs 225, and a BSPDN 196 is connected. The second contacts or contacts 192 extend through SACs 225, the SACs 225 horizontally aligned with top portions of the second set of isolation walls 190 of the second FET (e.g., bottom FET 45). The SACs 225 can include nitride and be referred to as nitride caps.

The threshold voltage (Vt) is defined by a first WFM 62 (bottom left), the Vt is defined by a second WFM 134 (bottom right) with a dipole material, the Vt is defined by a third WFM 180 (top left) and the Vt is defined by a third WFM 180 (top right) with a dipole material. The dipole material is a metal impurity material distributed in the HfO₂ and the interfacial layer. Therefore, in contrast to FIG. 9, two regions in FIG. 33 include the dipole material (top right and bottom right). The dipole material includes, but is not limited to at least, La, Y, Al, Ga, Nb, Ti, Mg. Moreover, it is contemplated that any of the devices (nanosheets and/or fins) can include a dipole material with the WFM to define a Vt.

In conclusion, the exemplary embodiments of the present invention present methods and devices for constructing stacked FETs having multi-Vt replacement metal gates. Some concerns for existing stacked FET structures are that the thermal budget of the top FET does not degrade the gate stack, being able to provide a multi-Vt solution, that is, metal gate patterning and dipole patterning, and being able to have both shared gates and independent gates. The exemplary embodiments of the present invention addressed such issues by providing novel structures for improved in-gate stack thermal budgets.

Regarding FIGS. 1-33, deposition is any process that grows, coats, or otherwise transfers a material onto the wafer. Available technologies include, but are not limited to, thermal oxidation, physical vapor deposition (PVD), chemical vapor deposition (CVD), electrochemical deposition (ECD), molecular beam epitaxy (MBE) and more recently, atomic layer deposition (ALD) among others. As used herein, “depositing” can include any now known or later developed techniques appropriate for the material to be deposited including but not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

The term “processing” as used herein includes deposition of material or photoresist, patterning, exposure, development, etching, cleaning, stripping, implanting, doping, stressing, layering, and/or removal of the material or photoresist as needed in forming a described structure.

It is to be understood that the present invention will be described in terms of a given illustrative architecture; however, other architectures, structures, substrate materials and process features and steps/blocks can be varied within the scope of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical mechanisms (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which usually include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present embodiments. The compounds with additional elements will be referred to herein as alloys.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of methods and structures providing for multi-Vt replacement metal gate bonded stacked FETs (which are intended to be illustrative and not limiting), it is noted that modifications and variations can be made by persons skilled in the art in light of the above teachings. It is therefore to be understood that changes may be made in the particular embodiments described which are within the scope of the invention as outlined by the appended claims. Having thus described aspects of the invention, with the details and particularity required by the patent laws, what is claimed and desired protected by Letters Patent is set forth in the appended claims.

1. A semiconductor structure comprising:
a first field effect transistor (FET), the first FET including at least a first set of fins and a second set of fins, the first set of fins surrounded by a first work function metal (WFM) and the second set of fins surrounded by a second WFM;
a second FET disposed directly over the first FET, the second FET including at least a first nanosheet stack and a second nanosheet stack, the first nanosheet stack surrounded by a third WFM and the second nanosheet stack surrounded by a third WFM with dipoles;
first contacts disposed from the first and second WFMs of the first FET to back-end-of-line (BEOL) components; and
second contacts disposed from a backside power delivery network (BSPDN) through the third WFM of the second FET to a top surface of the first and second WFMs of the first FET.

2. The semiconductor structure of claim 1, wherein the first FET is separated from the second FET by a bonding insulator stack such as oxide.

3. The semiconductor structure of claim 1, wherein the first, second, and third WFMs are each composed of a different material or different material stacks.

4. The semiconductor structure of claim 1, wherein isolation walls separate the plurality of nanosheet stacks of the second FET.

5. The semiconductor structure of claim 1, wherein isolation walls separate the first set of fins from the second set of fins of the first FET.

6. The semiconductor structure of claim 1, wherein the first set of fins of the first FET are vertically aligned with a nanosheet stack of the plurality of nanosheet stacks of the second FET.

7. The semiconductor structure of claim 1, wherein one of the first contacts extends through an isolation wall to directly contact one of the second contacts.

8. The semiconductor structure of claim 7, wherein a direct connection is created between the BEOL components and the BSPDN.

9. A semiconductor structure comprising:
a first field effect transistor (FET), the first FET including at least a first set of fins and a second set of fins, the first set of fins surrounded by a first work function metal (WFM) and the second set of fins surrounded by a second WFM;
a second FET disposed directly over the first FET, the second FET including at least a first nanosheet stack and a second nanosheet stack, the first nanosheet stack surrounded by a third WFM and the second nanosheet stack surrounded by a fourth WFM;
first contacts disposed from the first and second WFMs of the first FET to back-end-of-line (BEOL) components; and
second contacts disposed from a backside power delivery network (BSPDN), one second contact extending through the fourth WFM of the second FET to a top surface of the second WFM of the first FET.

10. The semiconductor structure of claim 9, wherein another second contact extends through the third WFM of the second FET to directly contact a top surface of a first contact extending through an isolation wall.

11. The semiconductor structure of claim 9, wherein the first FET is separated from the second FET by a bonding insulator stack such as oxide.

12. The semiconductor structure of claim 9, wherein the first, second, third, and fourth WFMs are each composed of a different material or different material stacks.

13. The semiconductor structure of claim 9, wherein an isolation wall separates the first nanosheet stack from the second nanosheet stack in the second FET.

14. The semiconductor structure of claim 9, wherein the first set of fins of the first FET are vertically aligned with the first nanosheet stack of the second FET and the second set of fins of the first FET are vertically aligned with the second nanosheet stack of the second FET.

15. A semiconductor structure comprising:
a first field effect transistor (FET), the first FET including at least a first nanosheet stack and a second nanosheet stack, the first nanosheet stack surrounded by a first work function metal (WFM) and the second nanosheet stack surrounded by a second WFM;
a second FET disposed directly over the first FET, the second FET including a third nanosheet stack and a fourth nanosheet stack, the third nanosheet stack surrounded by a third WFM and the fourth nanosheet stacks surrounded by a fourth WFM;
first contacts disposed from the first and second WFMs of the first FET to back-end-of-line (BEOL) components; and
second contacts disposed from a backside power delivery network (BSPDN) to the third WFM of the second FET.

16. The semiconductor structure of claim 15, wherein the first FET is separated from the second FET by a bonding insulator stack such as oxide.

17. The semiconductor structure of claim 15, wherein the first, second, third, and fourth WFMs are each composed of a different material or different material stack.

18. The semiconductor structure of claim 15, wherein a first set of isolation walls separate the first and second nanosheet stacks of the first FET and a second set of isolation walls separate the third and fourth nanosheet stacks of the second FET.

19. The semiconductor structure of claim 18, wherein the second contacts extend through nitride caps, the nitride caps horizontally aligned with top portions of the second set of isolation walls of the second FET.

20. The semiconductor structure of claim 19, wherein the first nanosheet stack of the first FET is vertically aligned with the third nanosheet stack of the second FET, and the second nanosheet stack of the first FET is vertically aligned with the fourth nanosheet stack of the second FET.
